(19) United States
(12) Patent Application Publication
(10) Pub. No.: US 2026/0302496 A1
(43) Pub. Date: Oct. 1, 2026

(54) BATTERY MODULE

(71) Applicant: SEMICONDUCTOR ENERGY LABORATORY CO., LTD., Atsugi-shi, Kanagawa-ken (JP)

(72) Inventors: Takeshi OSADA, Isehara, Kanagawa (JP); Yosuke TSUKAMOTO, Atsugi, Kanagawa (JP)

(21) Appl. No.: 19/477,862

(22) PCT Filed: May 13, 2024
(86) PCT No.: PCT/IB2024/054609

§ 371 Date: Oct. 23, 2025

(30) Foreign Application Priority Data
May 18, 2023 (JP) 2023-082539

(51) Int. Cl. H01M 50/284

(52) U.S. Cl. CPC H01M 50/284; H01M 2200/00

(57) ABSTRACT

A battery module that includes a circuit for safe control and that is capable of space-saving is to be provided. The battery module includes a flexible printed circuit (FPC) board, an exterior body, a positive electrode, and a negative electrode; the FPC board includes a first resin layer, a second resin layer, a third resin layer, a first metal layer positioned between the first resin layer and the second resin layer, and a second metal layer positioned between the second resin layer and the third resin layer; the first resin layer and the exterior body are bonded to each other at a sealing portion; the positive electrode includes a positive electrode current collector; the negative electrode includes a negative electrode current collector; and in a sealed space surrounded by the first resin layer, the exterior body, and the sealing portion, the first resin layer includes a first opening reaching the first metal layer, the first resin layer, the first metal layer, and the second resin layer each include a second opening reaching the second metal layer, the positive electrode current collector is connected to the first metal layer in the first opening, and the negative electrode current collector is connected to the second metal layer in the second opening.

### TECHNICAL FIELD

The invention disclosed in this specification and the like (hereinafter sometimes referred to as “the present invention” in this specification and the like) relates to a power storage device, a secondary battery, and the like. In particular, the present invention relates to a lithium-ion battery.

The present invention relates to an object, a method, or a manufacturing method. Alternatively, the present invention relates to a process, a machine, manufacture, or a composition (composition of matter). Alternatively, the present invention relates to a semiconductor device, a display device, a light-emitting device, a power storage device, a lighting device, an electronic device, a vehicle, or a manufacturing method thereof.

### BACKGROUND ART

In recent years, a variety of power storage devices such as lithium-ion batteries, lithium-ion capacitors, and air batteries have been actively developed. In particular, demands for lithium-ion batteries with high output and high energy density have rapidly grown with the development of the semiconductor industry, for portable information terminals such as mobile phones, smartphones, and laptop computers, portable music players, digital cameras, medical equipment, electric motor vehicles such as hybrid electric vehicles (HVs), electric vehicles (EVs), and plug-in hybrid electric vehicles (PHVs), and the like, and the lithium-ion batteries are essential as rechargeable energy supply sources for today's information society.

With the progress of reduction in size or thickness of a housing of a portable information terminal, it is desired to reduce the volume occupied by a battery and to increase the capacity of the battery in a portable information terminal.

It is known that a battery might generate heat because of an internal short circuit, overcharge, or the like and the battery enters thermal runaway due to heat, resulting in smoking, ignition, or explosion.

Conventionally, a battery control circuit (also referred to as a protection circuit in some cases) which prevents overcharge or overdischarge is mounted as an IC chip on a rigid board (printed wiring board) to ensure the safety of a battery. Note that a rigid board and a battery cell are connected to each other by welding a mount terminal portion of the rigid board and a lead terminal included in the battery cell in many cases; it is difficult to reduce the space of such a structure.

Thus, a power storage module in which a battery control circuit is provided over a flexible substrate and is attached to an external surface of a battery has been proposed (Patent Document 1).

An abnormality of a battery can occur not only inside the battery but also outside the battery. An example of an abnormality that occurs outside a battery includes a short circuit in a peripheral circuit of a battery, a so-called external short circuit. In view of this, a power storage module has been proposed to ensure safety when a peripheral circuit of a battery is wet with water or submerged under water (Patent Document 2).

### References

### [Patent Documents]

[Patent Document 1] Japanese Published Patent Application No. 2020-87540
[Patent Document 2] Japanese Published Patent Application No. 2022-177336

### SUMMARY OF THE INVENTION

### Problems to be Solved by the Invention

An object of one embodiment of the present invention is to achieve a structure of a battery module which includes a circuit for safely controlling a battery and can overcome space limitations due to miniaturization of a housing.

Another object of one embodiment of the present invention is to achieve a structure of a safe battery module in which a short circuit between a positive electrode and a negative electrode does not occur at the time of condensation, wetting with water, or submersion under water.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a battery module including a flexible printed circuit board, an exterior body, a positive electrode, and a negative electrode; the flexible printed circuit board includes a first resin layer, a second resin layer, a third resin layer, a first metal layer positioned between the first resin layer and the second resin layer, and a second metal layer positioned between the second resin layer and the third resin layer; the first resin layer and the exterior body are bonded to each other at a sealing portion; the positive electrode includes a positive electrode current collector; the negative electrode includes a negative electrode current collector; and in a sealed space surrounded by the first resin layer, the exterior body, and the sealing portion, the first resin layer includes a first opening reaching the first metal layer, the first resin layer, the first metal layer, and the second resin layer each include a second opening reaching the second metal layer, the positive electrode current collector is connected to the first metal layer in the first opening, and the negative electrode current collector is connected to the second metal layer in the second opening.

In the above, it is preferable that the first metal layer contain aluminum and the second metal layer contain copper.

In any one of the above battery modules, it is preferable that the flexible printed circuit board include a control circuit portion, the control circuit portion be connected to the positive electrode current collector through the first metal layer, and the control circuit portion be connected to the negative electrode current collector through the second metal layer.

In any one of the above battery modules, it is preferable that the flexible printed circuit board include a control circuit portion and a connection terminal, the control circuit portion include a transistor and a control IC, the second metal layer include a first portion and a second portion, a gate of the transistor be connected to the control IC, one of a source and a drain of the transistor be connected to the positive electrode current collector through the first portion, and the other of the source and the drain of the transistor be connected to the connection terminal through the second portion. The transistor is preferably a transistor using an oxide semiconductor. Alternatively, the transistor is preferably a vertical transistor.

### Effect of the Invention

One embodiment of the present invention can achieve a structure of a battery module which includes a circuit for safely controlling a battery and can overcome space limitations due to miniaturization of a housing.

Another embodiment of the present invention can achieve a structure of a safe battery module in which a short circuit between a positive electrode and a negative electrode does not occur at the time of condensation, wetting with water, or submersion under water.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a schematic perspective view of a structure example of a battery, and FIG. 1B is a schematic cross-sectional view of a structure example of a power storage portion of a battery module. FIG. 1C is a structure example of a connection terminal.

FIG. 2A to FIG. 2E are schematic top views illustrating structure examples of an FPC board.

FIG. 3A is a schematic top view illustrating a structure example of a positive electrode, FIG. 3B is a schematic top view illustrating a structure example of a separator, FIG. 3C is a schematic top view illustrating a structure example of a negative electrode, FIG. 3D is a schematic top view illustrating a structure example of an exterior body, and FIG. 3E is a schematic cross-sectional view illustrating the structure example of the exterior body.

FIG. 4A to FIG. 4C are schematic top views illustrating an example of a method for manufacturing a battery module.

FIG. 5A and FIG. 5B are schematic top views illustrating an example of a method for manufacturing a battery module.

FIG. 6A and FIG. 6B are schematic top views illustrating an example of a method for manufacturing a battery module.

FIG. 7A and FIG. 7B are schematic cross-sectional views illustrating structure examples of battery modules.

FIG. 8A is a schematic top view illustrating a structure example of a battery module including a control circuit portion, FIG. 8B is a schematic top view illustrating a structure example of the control circuit portion, and FIG. 8C is a circuit diagram illustrating a circuit structure of the battery module.

FIG. 9A is a schematic top view illustrating a structure example of a control circuit portion, FIG. 9B is a circuit diagram illustrating a circuit structure of a battery module, and FIG. 9C is a circuit diagram illustrating a circuit structure of a switch.

FIG. 10A and FIG. 10B illustrate a structure example of a semiconductor device.

FIG. 11A to FIG. 11H are diagrams illustrating examples of electronic devices.

FIG. 12A to FIG. 12D are diagrams illustrating examples of electronic devices.

FIG. 13A to FIG. 13C are diagrams illustrating examples of electronic devices.

FIG. 14A and FIG. 14B are diagrams illustrating examples of vehicles.

FIG. 15A is a diagram illustrating an electric bicycle, FIG. 15B is a diagram illustrating a secondary battery of the electric bicycle, and FIG. 15C is a diagram illustrating a motor scooter.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in drawings.

Note that in this specification and the like, ordinal numbers such as “first” and “second” are used for convenience and do not limit the number of components or the order of components (e.g., the order of steps or the stacking order of layers). In some cases, an ordinal number used for a component in a certain part in this specification is not the same as an ordinal number used for the component in another part in this specification or the scope of claims.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”.

In this specification and the like, terms for describing positioning, such as “over”, “under”, “above”, and “below”, are sometimes used for convenience to describe the positional relationship between components with reference to drawings. The positional relationship between components is changed as appropriate in accordance with the direction in which the components are described. Thus, the positional relationship is not limited to the terms described in this specification and the like, and can be described with another term as appropriate depending on the situation. For example, the expression “an insulator positioned over a conductor” can be replaced with the expression “an insulator positioned under a conductor” when the direction of a drawing illustrating these components is rotated by 180°.

Note that in this specification and the like, the term such as “over” or “below” does not necessarily mean that a component is placed “directly on” or “directly under” another component. For example, the expression “a gate electrode over a gate insulating film” does not exclude the case where there is an additional component between the gate insulating film and the gate electrode.

In this specification and the like, the terms such as “electrode” and “wiring” do not limit the functions of the components. For example, an “electrode” is used as part of a “wiring” in some cases, and vice versa. Furthermore, the terms “electrode” and “wiring” also include the case where a plurality of “electrodes” and “wirings” are formed in an integrated manner, for example.

Functions of a “source” and a “drain” are sometimes switched when a transistor of opposite polarity is used or when the direction of a current is changed in circuit operation, for example. Therefore, the terms “source” and “drain” can be switched in this specification.

In this specification, the expression “A is electrically connected to B” indicates a state where a path through which current can flow is formed between A and B when replaced with an equivalent circuit. The state where a path through which current can flow is formed between A and B includes the case where A is connected (directly connected) to B without a circuit element (e.g., a transistor and a resistor) therebetween and the case where A is connected (indirectly connected) to B with a circuit element therebetween. Note that a wiring is not included in a circuit element and the case where A is connected to B through a wiring is also regarded as A being directly connected to B.

For example, in the case where A is connected to B through a source and a drain of a transistor, a path through which current can flow through the source and the drain of the transistor is formed between A and B. Thus, regardless of whether the transistor is in an on state or an off state, it can be said that “A is electrically connected to B”. However, in the case where an insulator (e.g., a dielectric of a capacitor or a gate insulating film of a transistor) is included in the middle of the path from A to B, a path through which current can flow from A to B is not formed.

### Embodiment 1

In this embodiment, structure examples of a battery module of one embodiment of the present invention are described.

### [Battery Module]

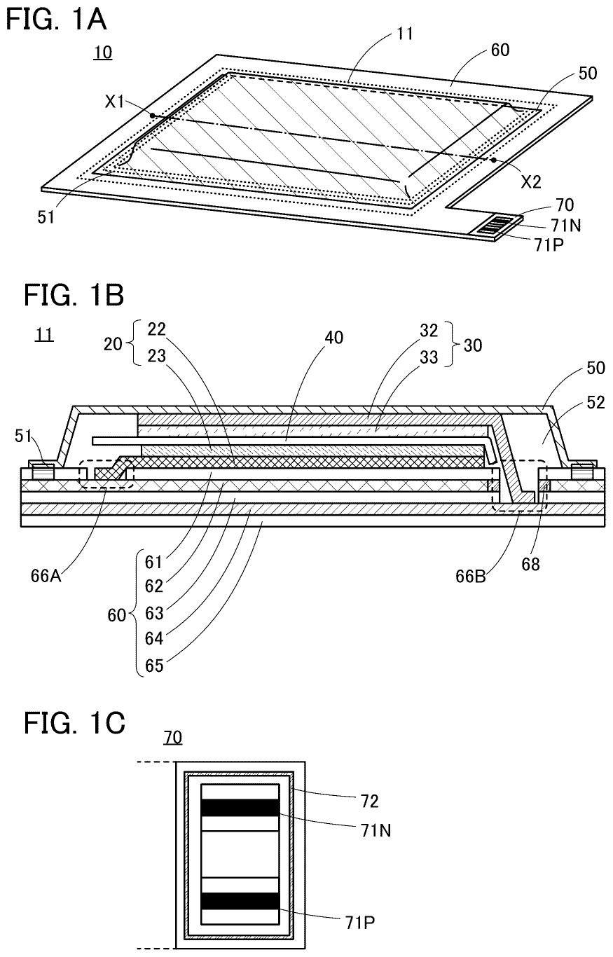

FIG. 1A to FIG. 1C are diagrams illustrating an example of a battery module of one embodiment of the present invention.

FIG. 1A is a perspective view of a battery module 10, and FIG. 1B is a schematic cross-sectional view taken along the dashed-dotted line X1-X2 in FIG. 1A. FIG. 1C is a schematic view illustrating a structure example of a connection terminal 70.

The battery module 10 includes a flexible printed circuit (FPC: Flexible Printed Circuits) board 60, an exterior body 50, and the connection terminal 70. The FPC board 60 and the exterior body 50 are bonded to each other at a sealing portion 51, so that a space surrounded by the FPC board 60 and the exterior body 50 is sealed, and the space is referred to as a sealed space 52 of the battery module 10. In the battery module 10, a portion including the sealed space 52, the exterior body 50, and the FPC board 60 in contact with the sealed space 52 and the sealing portion 51 is referred to as a power storage portion 11. The battery module 10 is connected to an electronic device, a vehicle, and the like described later via the connection terminal 70.

FIG. 1B is a schematic view illustrating an example of a cross-sectional structure of the power storage portion 11. The power storage portion 11 includes a positive electrode 20, a negative electrode 30, and a separator 40 in the sealed space 52. The positive electrode 20 includes a positive electrode current collector 22 and a positive electrode active material layer 23 over the positive electrode current collector 22. The negative electrode 30 includes a negative electrode current collector 32 and a negative electrode active material layer 33 over the negative electrode current collector 32. The separator 40 is positioned between the positive electrode active material layer 23 and the negative electrode active material layer 33 and is provided in order to prevent direct contact between the positive electrode 20 and the negative electrode 30. Although not illustrated, electrolytes are contained in a gap included in the positive electrode active material layer 23, a gap included in the negative electrode active material layer 33, and a gap included in the separator 40.

The FPC board 60 includes a first resin layer 61, a first metal layer 62, a second resin layer 63, a second metal layer 64, and a third resin layer 65. The first resin layer 61, the second resin layer 63, and the third resin layer 65 each have an insulating property, and the first metal layer 62 and the second metal layer 64 each have a conductive property.

In the FPC board 60, the first resin layer 61, the first metal layer 62, the second resin layer 63, the second metal layer 64, and the third resin layer 65 are stacked in this order, and the first metal layer 62 and the second metal layer 64 are insulated from each other.

The FPC board 60 includes the connection terminal 70. As described later, the connection terminal 70 includes a plus terminal 71P electrically connected to the first metal layer 62 and a minus terminal 71N electrically connected to the second metal layer 64. Note that the connection terminal 70 may include a sealing rubber 72 as illustrated in FIG. 1C. The sealing rubber 72 is in close contact with a peripheral portion of a connection terminal of an electronic device or the like to which the battery module 10 is connected, whereby the plus terminal 71P and the minus terminal 71N can be sealed.

In the FPC board 60, the first resin layer 61 includes a first opening portion 66A reaching the first metal layer 62. In the FPC board 60, the first resin layer 61, the first metal layer 62, and the second resin layer 63 include a second opening portion 66B reaching the second metal layer 64. Note that the first opening portion 66A and the second opening portion 66B are positioned in the sealed space 52.

In the first opening portion 66A, the positive electrode current collector 22 is connected to the first metal layer 62. In the second opening portion 66B, the negative electrode current collector 32 is connected to the second metal layer 64. That is, in the sealed space 52, the positive electrode current collector 22 is connected to the first metal layer 62, and the negative electrode current collector 32 is connected to the second metal layer 64. Note that in order to prevent electrical contact between the first metal layer 62 and the negative electrode current collector 32 in the second opening portion 66B, the first metal layer 62 is preferably not exposed in the second opening portion 66B. For example, as illustrated in FIG. 1B, an insulating portion 68 is preferably provided.

In addition, the first metal layer 62 and the second metal layer 64 are not exposed from a side end portion of the FPC board 60.

In the battery module 10 of one embodiment of the present invention described above, the FPC board 60 functions not only as a circuit board that connects the power storage portion 11 to the connection terminal, but also as an exterior material that seals the sealed space 52 of the power storage portion 11. As described later, a control circuit portion can be provided in the FPC board 60. Thus, the battery module 10 of one embodiment of the present invention can achieve a structure of a battery module which includes a circuit for safely controlling a battery and can overcome space limitations due to miniaturization of the housing.

The battery module 10 of one embodiment of the present invention described above has a structure of a safe battery module in which a portion electrically connected to the positive electrode 20 (e.g., the first metal layer 62) and a portion electrically connected to the negative electrode 30 (e.g., the second metal layer 64) are not exposed and a short circuit between the positive electrode 20 and the negative electrode 30 does not occur at the time of condensation, wetting with water, or submersion under water.

### [FPC Board]

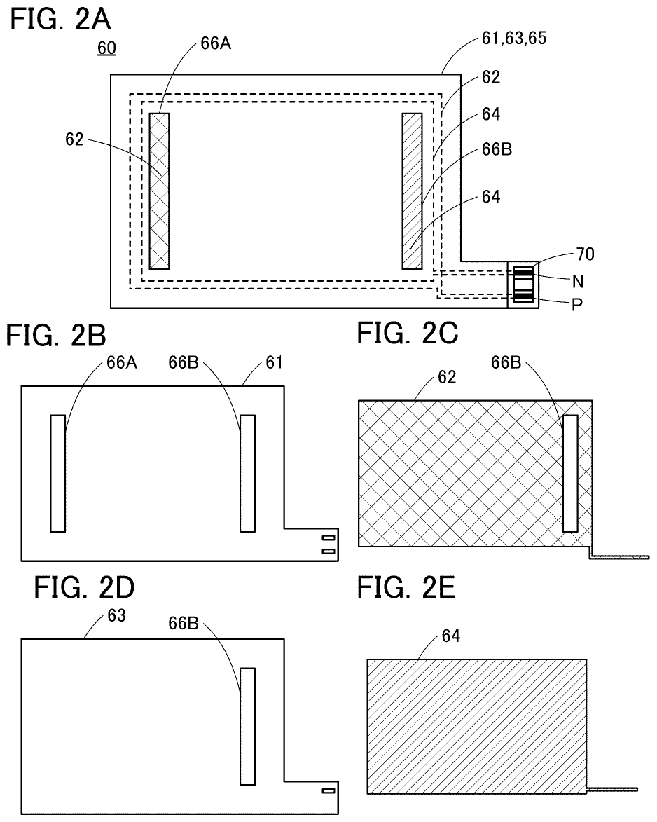

An example of the FPC board 60 is described with reference to FIG. 2A to FIG. 2E.

FIG. 2A is a schematic top view of the FPC board 60, FIG. 2B is a schematic top view of the first resin layer 61, FIG. 2C is a schematic top view of the first metal layer 62, FIG. 2D is a schematic top view of the second resin layer 63, and FIG. 2E is a schematic top view of the second metal layer 64.

As illustrated in FIG. 2A, in the top view of the FPC board 60, the first metal layer 62 and the second metal layer 64 overlap with each other so as not to protrude from the outer edges of the first resin layer 61, the outer edges of the second resin layer 63, and the outer edges of the third resin layer 65. Thus, the first metal layer 62 and the second metal layer 64 are not exposed from the side end portions of the FPC board 60.

As illustrated in FIG. 2B, the first resin layer 61 includes the first opening portion 66A and the second opening portion 66B. As illustrated in FIG. 2C, the first metal layer 62 includes the second opening portion 66B. As illustrated in FIG. 2D, the second resin layer 63 includes the second opening portion 66B.

Note that although FIG. 2E illustrates a structure example in which the second metal layer 64 does not include an opening portion, the shape of the second metal layer 64 is not limited thereto; the second metal layer 64 may include an opening portion and be used as a circuit wiring included in the FPC board 60.

Note that in the top view of the FPC board 60, the second metal layer 64 needs to exist in a position overlapping with the second opening portion 66B included in the first metal layer 62. One reason is that in the case where the second metal layer 64 does not exist in a position overlapping with the second opening portion 66B, the negative electrode current collector 32 and the second metal layer 64 cannot be connected to each other. Another reason is that in the battery module 10, the first metal layer 62 has a function of preventing entry of air and water into the sealed space 52 from the outside of the battery module; thus, in the case where the second metal layer 64 does not exist in a position overlapping with the second opening portion 66B, it is difficult to prevent entry of air and water from the outside of the battery into the sealed space 52.

As illustrated in FIG. 2A, FIG. 2C, and FIG. 2E, the first metal layer 62 is electrically connected to the plus terminal 71P of the connection terminal 70, and the second metal layer 64 is electrically connected to the minus terminal 71N of the connection terminal 70.

Since the first resin layer 61 might be in contact with an electrolyte in the power storage portion 11, a material that does not react with the electrolyte is preferably used for the first resin layer 61. For example, as the first resin layer 61, a film formed of a material such as polypropylene, polyethylene, polycarbonate, ionomer, or polyamide can be used. In particular, polypropylene is preferably used for the first resin layer 61 because it is the same material as a fusion layer of an aluminum laminate film that is readily available as an exterior body and thus the sealing portion 51 can be favorably formed. The thickness of the first resin layer 61 is preferably greater than or equal to 10 μm and less than or equal to 500 μm, further preferably greater than or equal to 20 μm and less than or equal to 200 μm, and still further preferably greater than or equal to 25 μm and less than or equal to 100 μm.

The first metal layer 62 is connected to the positive electrode current collector 22 in the first opening portion 66A of the power storage portion 11, and thus is preferably formed using a material that is stable even at the potential of the positive electrode. For example, as the first metal layer 62, any one of aluminum foil, stainless steel foil, chromium foil, nickel foil, molybdenum foil, tantalum foil, tungsten foil, gold foil, platinum foil, iridium foil, and the like can be used. In particular, aluminum foil is lightweight and inexpensive, and thus is suitable for the first metal layer 62. The thickness of the first metal layer 62 is preferably greater than or equal to 10 μm and less than or equal to 100 μm, further preferably greater than or equal to 10 μm and less than or equal to 50 μm, still further preferably greater than or equal to 10 μm and less than or equal to 30 μm, yet still further preferably greater than or equal to 10 μm and less than or equal to 20 μm.

For the second resin layer 63, a film formed of polyamide such as nylon, polyester such as polyethylene terephthalate, or polyimide can be used, for example. The thickness of the second resin layer 63 is preferably greater than or equal to 10 μm and less than or equal to 500 μm, further preferably greater than or equal to 20 μm and less than or equal to 200 μm, still further preferably greater than or equal to 25 μm and less than or equal to 100 μm.

The second metal layer 64 is connected to the negative electrode current collector 32 in the second opening portion 66B of the power storage portion 11, and thus is preferably formed using a material that is stable even at the potential of the negative electrode. For example, as the second metal layer 64, any one of copper foil, stainless steel foil, chromium foil, nickel foil, molybdenum foil, tantalum foil, tungsten foil, gold foil, platinum foil, iridium foil, and the like can be used. In particular, copper foil is preferable for the second metal layer 64 because of its low reactivity with lithium at the negative electrode potential and its relatively lower cost than other metal foils. The thickness of the second metal layer 64 is preferably greater than or equal to 10 μm and less than or equal to 100 μm, further preferably greater than or equal to 10 μm and less than or equal to 50 μm, still further preferably greater than or equal to 10 μm and less than or equal to 30 μm, yet still further preferably greater than or equal to 10 μm and less than or equal to 20 μm.

For the third resin layer 65, a film formed of polyamide such as nylon, polyester such as polyethylene terephthalate, or polyimide can be used, for example. The thickness of the third resin layer 65 is preferably greater than or equal to 10 μm and less than or equal to 500 μm, further preferably greater than or equal to 20 μm and less than or equal to 200 μm, still further preferably greater than or equal to 25 μm and less than or equal to 100 μm.

### [Method for Manufacturing Battery Module]

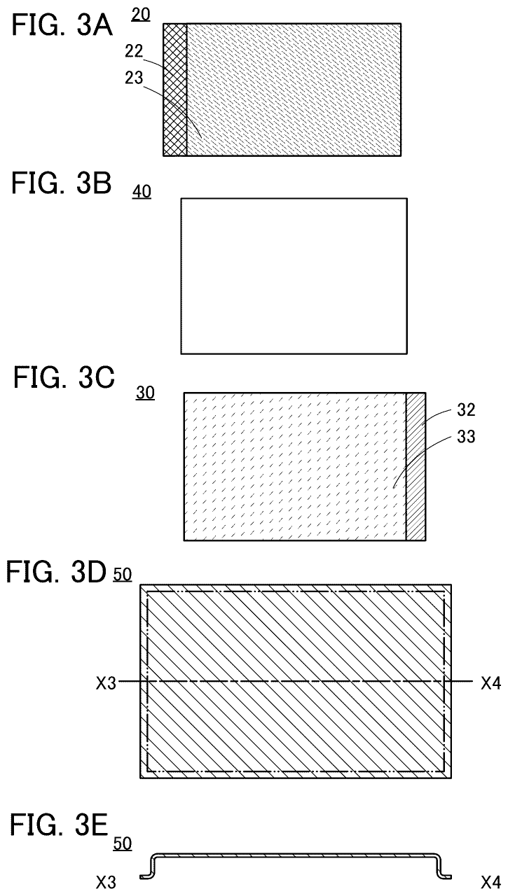

An example of a method for manufacturing the battery module 10 is described with reference to FIG. 3A to FIG. 5B.

FIG. 3A to FIG. 3D are schematic top views of components of the battery module 10.

The positive electrode 20 includes the positive electrode current collector 22, and the positive electrode active material layer 23 is provided on one or both surfaces of the positive electrode current collector 22. FIG. 1B and FIG. 3A illustrate an example in which the positive electrode active material layer 23 is provided on one surface of the positive electrode current collector 22. As illustrated in FIG. 3A, the surface of the positive electrode current collector 22 including the positive electrode active material layer 23 includes a region where the positive electrode current collector 22 is exposed. In the region, the positive electrode current collector 22 and the FPC board 60 can be connected to each other.

The negative electrode 30 includes the negative electrode current collector 32, and the negative electrode active material layer 33 is provided on one or both surfaces of the negative electrode current collector 32. FIG. 1B and FIG. 3C illustrate an example in which the negative electrode active material layer 33 is provided on one surface of the negative electrode current collector 32. As illustrated in FIG. 3C, the surface of the negative electrode current collector 32 including the negative electrode active material layer 33 includes a region where the negative electrode current collector 32 is exposed. In the region, the negative electrode current collector 32 and the FPC board 60 can be connected to each other.

Note that the separator 40 illustrated in FIG. 3B is larger than the region where the positive electrode 20 and the negative electrode 30 overlap with each other in the top view of the battery module 10.

The exterior body 50 illustrated in FIG. 3D is larger than the positive electrode 20, the negative electrode 30, and the separator 40 in the top view of the battery module 10.

At this time, drawing of the exterior body 50 may be performed at a position indicated by a dashed double-dotted line in the drawing. FIG. 3E is a schematic cross-sectional view of the drawn exterior body 50 in the dashed-dotted line E3-E4 in FIG. 3D. In the case where the battery module 10 includes a plurality of positive electrodes 20, a plurality of separators, and a plurality of negative electrodes 30, the use of the drawn exterior body 50 can reduce interference between components of the battery module 10.

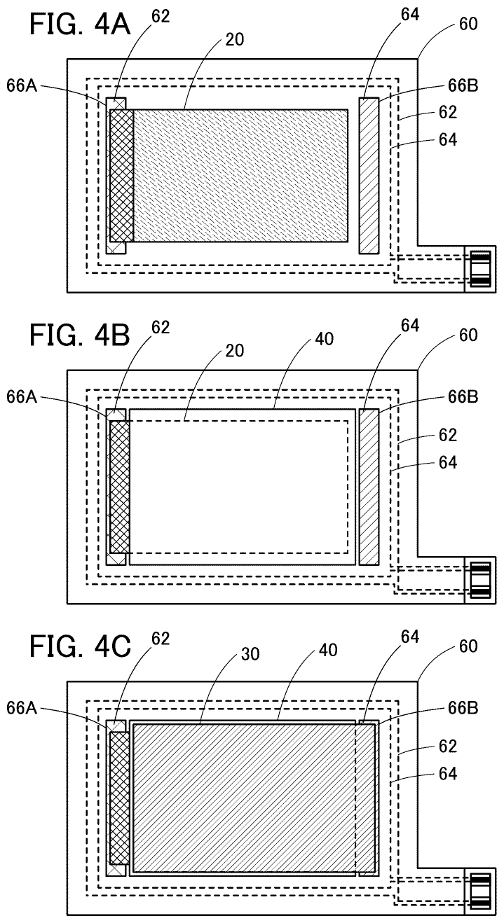

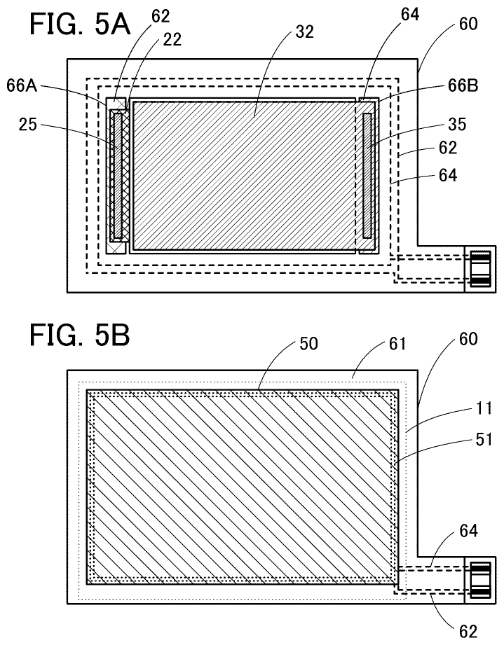

FIG. 4A to FIG. 5B are schematic top views illustrating a manufacturing process of the battery module 10. Described here is an example of a manufacturing method using one FPC board 60, one positive electrode 20 (also referred to as a single-side-coated positive electrode) including the positive electrode active material layer 23 on one surface of the positive electrode current collector 22, one separator 40, one negative electrode 30 (also referred to as a single-side-coated negative electrode) including the negative electrode active material layer 33 on one surface of the negative electrode current collector 32, and one exterior body 50.

First, as illustrated in FIG. 4A, the positive electrode 20 overlaps with the surface of the FPC board 60 on the first resin layer side. At this time, the positive electrode 20 is overlapped such that the surface of the positive electrode current collector 22 not including the positive electrode active material layer 23 faces the FPC board 60.

Next, as illustrated in FIG. 4B, the separator 40 overlaps with the positive electrode 20.

Next, as illustrated in FIG. 4C, the negative electrode 30 overlaps with the separator 40. At this time, the negative electrode 30 is overlapped such that the negative electrode active material layer 33 faces the separator 40.

Next, as illustrated in FIG. 5A, the positive electrode current collector 22 is connected to the first metal layer 62. As a method for connecting the positive electrode current collector 22 to the first metal layer 62, ultrasonic welding or the like can be employed. A connection portion of the positive electrode current collector 22 and the first metal layer 62 is illustrated as a connection portion 25 in the drawing.

In a manner similar to the above, the negative electrode current collector 32 is connected to the second metal layer 64. As a method for connecting the negative electrode current collector 32 to the second metal layer 64, ultrasonic welding or the like can be employed. A connection portion of the negative electrode current collector 32 and the second metal layer 64 is illustrated as a connection portion 35 in the drawing.

Next, an electrolyte is injected into the space included in the positive electrode active material layer 23, the space included in the negative electrode active material layer 33, and the space included in the separator 40, and then, as illustrated in FIG. 5B, the exterior body 50 is overlapped to cover the positive electrode 20, the negative electrode 30, the separator 40, the first opening portion 66A, and the second opening portion 66B. After that, the exterior body 50 and the first resin layer 61 of the FPC board 60 are bonded to each other at the sealing portion 51. An adhesive can be used for the bonding. Alternatively, part of the exterior body 50 and part of the first resin layer 61 can be bonded to each other by heat fusion bonding.

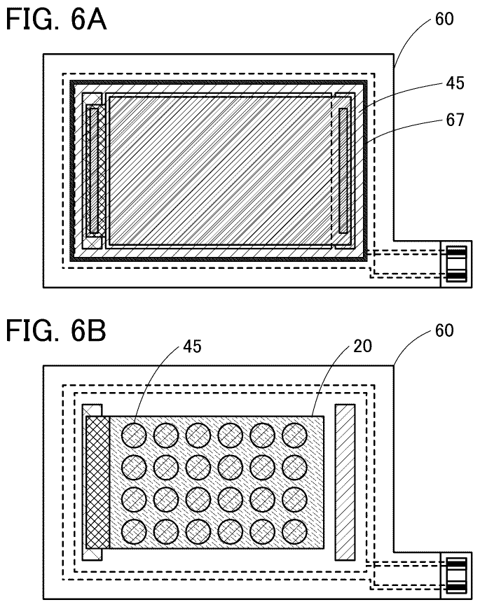

An example of a method for injecting an electrolyte is described with reference to FIG. 6A and FIG. 6B.

As a method for injecting an electrolyte, for example, as illustrated in FIG. 6A, a bank 67 can be provided such that an electrolyte 45 can be injected therein to fill the interior with the electrolyte 45.

As another method for injecting an electrolyte, for example, a method illustrated in FIG. 6B may be employed in which the electrolyte 45 is dripped on each of the positive electrode 20, the separator 40, and the negative electrode 30 when they overlap with each other, whereby the space included in the positive electrode active material layer 23, the space included in the negative electrode active material layer 33, and the space included in the separator 40 are impregnated with the electrolyte 45.

In such a manner, the battery module 10 of one embodiment of the present invention can be manufactured.

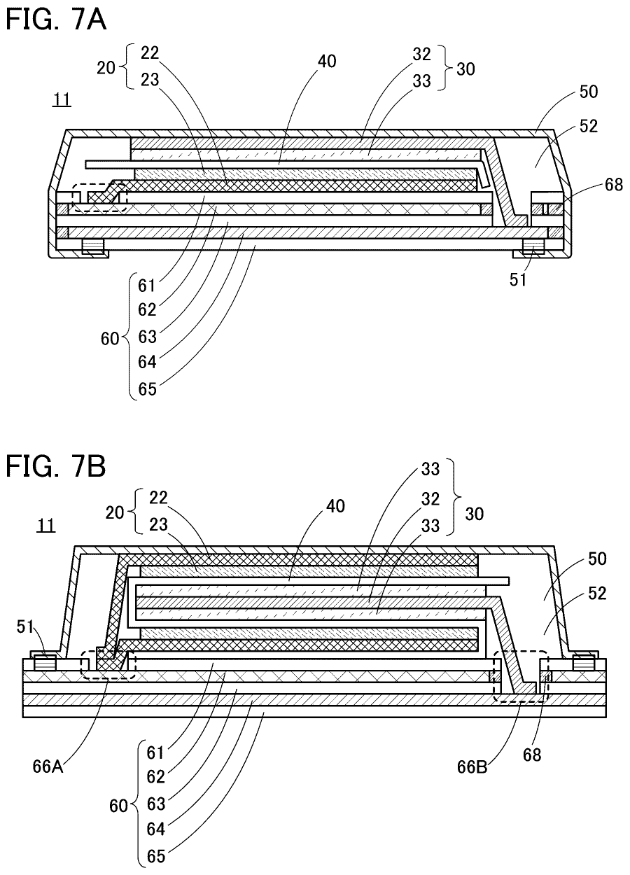

As a structure different from that in FIG. 1 and the like, for example, as illustrated in FIG. 7A, the sealing portion 51 of the exterior body 50 and the FPC board 60 can be provided in a position in contact with the third resin layer 65 of the FPC board 60. With such a structure, the sealing portion 51 can be provided inside the power storage portion 11 in a plan view, so that a more space-saving structure of the battery module can be achieved.

As a structure different from that in FIG. 1 and the like, for example, as illustrated in FIG. 7B, the separator 40 can have a zigzag structure with a plurality of positive electrodes 20 and a plurality of negative electrodes 30. Such a structure can further prevent direct contact between the positive electrode 20 and the negative electrode 30.

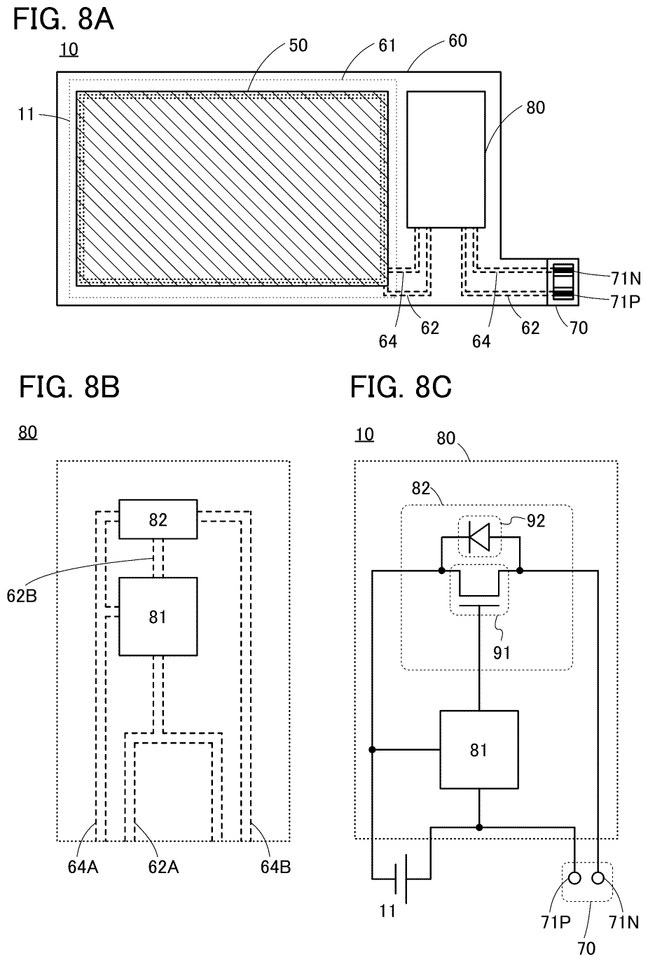

As a structure different from that in FIG. 1 and the like, for example, as illustrated in FIG. 8A, the battery module of one embodiment of the present invention can have a structure in which the FPC board 60 includes a control circuit portion 80 and the power storage portion 11 and the connection terminal 70 are connected to each other via the control circuit portion 80.

### [Structure Example 1 of Control Circuit Portion]

An example of the control circuit portion 80 is described with reference to FIG. 8B and FIG. 8C. FIG. 8B is a schematic top view illustrating an example of the control circuit portion 80 in FIG. 8A. FIG. 8C is a circuit diagram of the battery module 10 illustrated in FIG. 8A and FIG. 8B.

As illustrated in FIG. 8B, the control circuit portion 80 includes a control IC (Integrated Circuit) 81 and a switch 82. In the control circuit portion 80 illustrated in FIG. 8B, the first metal layer 62 is divided into a first metal layer 62A and a first metal layer 62B. The second metal layer 64 is divided into a second metal layer 64A and a second metal layer 64B.

As illustrated in FIG. 8A and FIG. 8B, the first metal layer 62A is connected to the power storage portion 11, the control IC 81, and the plus terminal 71P. The second metal layer 64A is connected to the power storage portion 11, the control IC 81, and the switch 82. Note that, as illustrated in FIG. 1B, the first metal layer 62A is connected to the positive electrode current collector 22 in the power storage portion 11, and the second metal layer 64A is connected to the negative electrode current collector 32 in the power storage portion 11.

As illustrated in FIG. 8B, the first metal layer 62B is connected to the control IC 81 and the switch 82. The second metal layer 64B is connected to the switch 82 and the minus terminal 71N.

As described above, the first metal layer 62 and the second metal layer 64 included in the FPC board 60 can be used as wiring layers that connect elements such as the control IC 81, the switch 82, and the connection terminal 70. The wiring shapes of the first metal layer 62 and the second metal layer 64 illustrated in FIG. 8B are examples for description; the first metal layer 62 and the second metal layer 64 may intersect with each other. In addition to the elements illustrated in FIG. 8B, elements such as a resistor and a capacitor may be provided as appropriate.

The control IC 81 has a function of sensing the voltage of the power storage portion 11. For example, the control IC 81 can control the switch 82 to interrupt current in the case where an abnormality of the voltage of the power storage portion 11 is detected.

The switch 82 can include a transistor 91. As illustrated in FIG. 8C, when the transistor 91 and a diode 92 are provided in parallel in the switch 82, a current flow in one direction can be interrupted. For example, in the structure illustrated in FIG. 8C, while current flowing through the transistor 91 is interrupted in the case where the control IC 81 detects an overcharge voltage, a discharge current from the power storage portion 11 can pass through the diode 92.

### [Structure Example 2 of Control Circuit Portion]

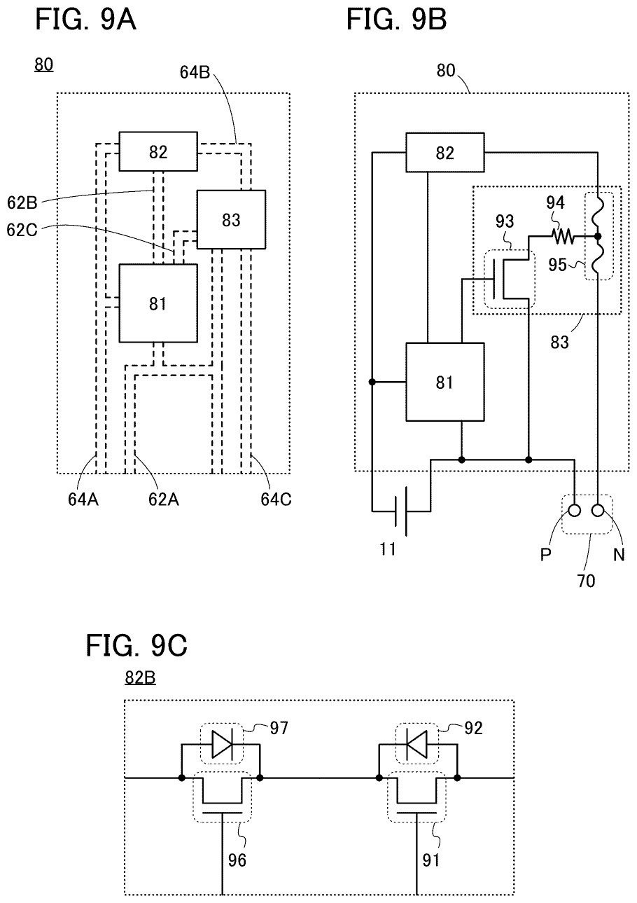

Another example of the control circuit portion 80 is described with reference to FIG. 9A and FIG. 9B. FIG. 9A is a schematic top view illustrating an example of the control circuit portion 80 in FIG. 8A. FIG. 9B is a circuit diagram of the battery module 10 illustrated in FIG. 8A and FIG. 9A.

As illustrated in FIG. 9A, the control circuit portion 80 includes the control IC 81, the switch 82, and a SCP (Self Control Protector) element 83. In the control circuit portion 80 illustrated in FIG. 9A, the first metal layer 62 is divided into the first metal layer 62A, the first metal layer 62B, and a first metal layer 62C. The second metal layer 64 is divided into the second metal layer 64A, the second metal layer 64B, and a second metal layer 64C.

As illustrated in FIG. 8A and FIG. 9A, the first metal layer 62A is connected to the power storage portion 11, the control IC 81, the SCP element 83, and the plus terminal 71P. The second metal layer 64A is connected to the power storage portion 11, the control IC 81, and the switch 82. Note that, as illustrated in FIG. 1B, the first metal layer 62A is connected to the positive electrode current collector 22 in the power storage portion 11, and the second metal layer 64A is connected to the negative electrode current collector 32 in the power storage portion 11.

As illustrated in FIG. 9A, the first metal layer 62B is connected to the control IC 81 and the switch 82. The first metal layer 62C is connected to the control IC 81 and the SCP element 83. The second metal layer 64B is connected to the switch 82 and the SCP element 83. The second metal layer 64C is connected to the SCP element 83 and the minus terminal 71N.

As described above, the first metal layer 62 and the second metal layer 64 included in the FPC board 60 can be used as wiring layers that connect elements such as the control IC 81, the switch 82, the SCP element 83, and the connection terminal 70. The wiring shapes of the first metal layer 62 and the second metal layer 64 illustrated in FIG. 9A are examples for description; the first metal layer 62 and the second metal layer 64 may intersect with each other. In addition to the elements illustrated in FIG. 9A, elements such as a resistor and a capacitor may be provided as appropriate.

The control IC 81 and the switch 82 described in [Structure example 1 of control circuit portion 80] can be used. As illustrated in FIG. 9B, the SCP element 83 includes a transistor 93, a resistor 94, and a fuse 95. The transistor 93 included in the SCP element 83 can supply current to the resistor 94 under the control of the control IC 81. In the SCP element 83, when current flows through the resistor 94, the resistor 94 generates heat, whereby the fuse 95 adjacent to the resistor 94 is melted down. In this manner, the power storage portion 11 can be separated from an external circuit. That is, it can be said that the control circuit portion 80 illustrated in FIG. 9A and FIG. 9B is a control circuit including the switch 82 for primary protection and the SCP element 83 for secondary protection.

Note that in [Structure example 1 of control circuit portion 80] and [Structure example 2 of control circuit portion 80], as the switch 82, a circuit structure of a switch 82B illustrated in FIG. 9C may be employed instead of that illustrated in FIG. 8C.

The switch 82B has a structure in which the transistor 91 and the diode 92 connected in parallel and a transistor 96 and a diode 97 connected in parallel are connected in series, and the diode 92 and the diode 97 are connected in opposite directions to each other. Such a structure enables the charge current and the discharge current to be controlled independently.

### [Transistor]

Next, a structure of a transistor that can be used as the transistor 91, the transistor 93, and the transistor 96 used in the structure examples illustrated in FIG. 8C, FIG. 9B, and FIG. 9C is described.

As the transistor, a silicon transistor or a transistor using an oxide semiconductor can be used. A charge control circuit or a battery control system that includes a memory circuit including a transistor using an oxide semiconductor is referred to as a BTOS (Battery operating system or Battery oxide semiconductor) in some cases.

A planar transistor, a trench transistor, or a vertical transistor can be used as the transistor. Alternatively, a plurality of the above transistors can be used in combination as the transistor.

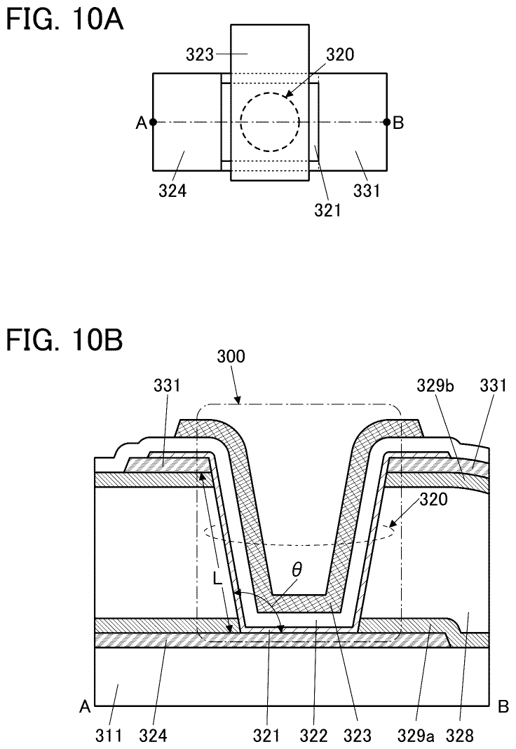

A vertical transistor is described with reference to FIG. 10A and FIG. 10B.

The vertical transistor includes a semiconductor layer, a gate insulating layer, a gate electrode, a first electrode, and a second electrode. The first electrode functions as one of a source electrode and a drain electrode, and the second electrode functions as the other.

The second electrode is provided over the first electrode. Between the first electrode and the second electrode, an insulating layer functioning as a spacer is provided. An opening portion reaching the first electrode is provided in the spacer, and the semiconductor layer is provided in contact with the first electrode, the second electrode, and a side wall (also referred to as a side surface) of the insulating layer in the opening portion. The gate insulating layer and the gate electrode are provided to cover the semiconductor layer.

Here, the first electrode and the second electrode may be provided independently from the semiconductor layer or part of the semiconductor layer may function as the first electrode or the second electrode.

The transistor with the above structure has the source electrode and the drain electrode positioned at different heights, so that the current flowing through the semiconductor layer flows in the height direction. In other words, the channel length direction can be regarded as having a height-direction (vertical direction) factor; accordingly, the transistor can also be referred to as a VFET (Vertical Field Effect Transistor), a vertical transistor, a vertical-channel transistor, and the like.

The above transistor enables the source electrode, the semiconductor layer, and the drain electrode to be provided to overlap with each other, making it possible to significantly reduce the area occupied by the transistor as compared with a so-called planar transistor (also referred to as a lateral transistor, a lateral FET (LFET), or the like) in which a semiconductor layer is positioned on a flat plane.

Moreover, since the channel length of the transistor can be precisely controlled by the thickness of the insulating layer, a variation in the channel length can be extremely reduced as compared with that of a planar transistor. Furthermore, by reducing the thickness of the insulating layer, a transistor with an extremely short channel length can be manufactured. For example, a transistor can be manufactured with a channel length of less than or equal to 2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm and greater than or equal to 5 nm, greater than or equal to 7 nm, or greater than or equal to 10 nm.

It is particularly preferable to use a metal oxide film having semiconductor characteristics (also referred to as an oxide semiconductor film) for the semiconductor layer because it achieves both high performance and high productivity. In particular, it is further preferable to use an oxide semiconductor film having crystallinity because it achieves high reliability.

More specific examples are described below with reference to drawings.

FIG. 10A is a top view of a transistor 300, and FIG. 10B is a cross-sectional view taken along the cut line A-B in FIG. 10A. Note that some components (e.g., insulating layers) are omitted in FIG. 10A.

The transistor 300 is provided over a substrate 311 and includes a semiconductor layer 321, an insulating layer 322, a conductive layer 323, a conductive layer 324, and a conductive layer 331.

As illustrated in FIG. 10B, the conductive layer 324 is provided over the substrate 311, and an insulating layer 329a, an insulating layer 328, and an insulating layer 329b are provided in this order to cover the conductive layer 324. Moreover, the conductive layer 331 is provided over the insulating layer 329b. An opening portion 320 reaching the conductive layer 324 is provided in the conductive layer 331, the insulating layer 329b, the insulating layer 328, and the insulating layer 329a. For example, it can also be said that side walls (side surfaces) of the conductive layer 331, the insulating layer 329b, the insulating layer 328, and the insulating layer 329a in the opening portion 320 overlap with the conductive layer 324.

The semiconductor layer 321 is in contact with the top surface of the conductive layer 324 positioned at the bottom of the opening portion 320, the side surfaces of the insulating layer 329a, the insulating layer 328, the insulating layer 329b, and the conductive layer 331 in the opening portion 320, and the top surface of the conductive layer 331. A portion of the semiconductor layer 321 that is in contact with the conductive layer 331 functions as one of a source region and a drain region, a portion of the semiconductor layer 321 that is in contact with the conductive layer 324 functions as the other of the source region and the drain region, and a region of the semiconductor layer 321 between the above portions (in particular, a region in contact with the insulating layer 328) functions as a region where a channel is formed (a channel formation region). It is preferable that in the semiconductor layer 321, a region in contact with the insulating layer 329a and a region in contact with the insulating layer 329b have a higher carrier concentration and a lower resistance than the channel formation region.

The insulating layer 322 functioning as the gate insulating layer is provided to cover the insulating layer 329b, the conductive layer 331, and the semiconductor layer 321. In addition, the conductive layer 323 functioning as the gate electrode is provided to cover the insulating layer 322.

The semiconductor layer 321 includes a portion that is in contact with the side surface of the insulating layer 328 and functions as a channel formation region. In the opening portion 320, the insulating layer 322 includes a portion facing the side surface of the insulating layer 328 with the semiconductor layer 321 therebetween. The conductive layer 323 includes a portion facing the side surface of the insulating layer 328 with the semiconductor layer 321 and the insulating layer 322 therebetween. An interface between the semiconductor layer 321 and the insulating layer 322 and an interface between the insulating layer 322 and the conductive layer 323 each include a portion parallel to the side surface of the insulating layer 328.

The semiconductor layer 321 preferably includes a metal oxide (an oxide semiconductor).

Examples of the metal oxide that can be used for the semiconductor layer 321 include In oxide, Ga oxide, and Zn oxide. The metal oxide preferably contains at least In or Zn. The metal oxide preferably contains two or three selected from In, an element M, and Zn. Note that the element Mis a metal element or a metalloid element that has a high bonding energy with oxygen, such as a metal element or a metalloid element whose bonding energy with oxygen is higher than that of In, for example. Specific examples of the element M include Al, Ga, Sn, Y, Ti, V, Cr, Mn, Fe, Co, Ni, Zr, Mo, Hf, Ta, W, La, Ce, Nd, Mg, Ca, Sr, Ba, B, Si, Ge, and Sb. The element M included in the metal oxide is preferably one or more kinds of the above elements, and specifically, the element M is preferably one or more kinds selected from Al, Ga, Y, and Sn, and is further preferably Ga. Hereinafter, a metal oxide containing In, M, and zinc is referred to as In—M—Zn oxide in some cases. In this specification and the like, a metal element and a metalloid element are collectively referred to as a “metal element” in some cases, and a “metal element” in this specification and the like contains a metalloid element in some cases.

In the case where the metal oxide is In-M-Zn oxide, the atomic ratio of In is preferably higher than or equal to the atomic ratio of M in the In-M-Zn oxide. Examples of the atomic ratio of the metal elements of such In-M-Zn oxide include In: M: Zn=1:1:1, In: M: Zn=1:1:1.2, In: M: Zn=2:1:3, In: M: Zn=3:1:2, In: M: Zn=4:2:3, In: M: Zn=4:2:4.1, In: M: Zn=5:1:3, In: M: Zn=5:1:6, In: M: Zn=5:1:7, In: M: Zn=5:1:8, In: M: Zn=6:1:6, and In: M: Zn=5:2:5 or a composition in the neighborhood thereof. Note that a composition in the neighborhood includes the range of ±30 % of an intended atomic ratio. By increasing the atomic ratio of indium in the metal oxide, the on-state current, field-effect mobility, or the like of the transistor can be increased.

The atomic ratio of In may be less than the atomic ratio of M in the In—M—Zn oxide. Examples of the atomic ratio of the metal elements of such In—M—Zn oxide include In: M: Zn=1:3:2, In: M: Zn=1:3:3, In: M: Zn=1:3:4 or a composition in the neighborhood thereof. By increasing the atomic ratio of M in the metal oxide, generation of oxygen vacancies can be inhibited.

For the semiconductor layer 321, for example, In—Zn oxide, In—Ga oxide, In—Sn oxide, In—Ti oxide, In—Ga—Al oxide, In—Ga—Sn oxide, In—Ga—Zn oxide, In—Sn—Zn oxide, In—Al—Zn oxide, In—Ti—Zn oxide, In—Ga—Sn—Zn oxide, or In—Ga—Al—Zn oxide can be used. Alternatively, Ga-Zn oxide may be used.

Note that the metal oxide may contain, instead of or in addition to indium, one or more kinds of metal elements with a large period number. The larger the overlap between orbits of metal elements is, the higher the carrier conductivity of the metal oxide tends to be. Thus, a transistor containing a metal element with a large period number can have high field-effect mobility in some cases. Examples of the metal element with a large period number include metal elements belonging to Period 5 and metal elements belonging to Period 6. Specific examples of the metal elements include Y, Zr, Ag, Cd, Sn, Sb, Ba, Pb, Bi, La, Ce, Pr, Nd, Pm, Sm, and Eu. Note that La, Ce, Pr, Nd, Pm, Sm, and Eu are referred to as light rare earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

A sputtering method or an atomic layer deposition (ALD) method can be suitably used to form the metal oxide. Note that in the case where the metal oxide is formed by a sputtering method, the composition of the deposited metal oxide may be different from the composition of a target. In particular, the content percentage of zinc in the deposited metal oxide may be reduced to approximately 50 % of that of the target.

In this specification and the like, the content of a certain metal element in the metal oxide refers to the ratio of the number of atoms of the element to the total number of atoms of metal elements contained in the metal oxide. In the case where a metal oxide contains a metal element X, a metal element Y, and a metal element Z whose atomic numbers are respectively represented by A_{X}, A_{Y}, and A_{Z}, the content of the metal element X can be represented by Ax/(A_{X}+A_{Y}+A_{Z}). Moreover, in the case where the atomic ratio of the metal element X, the metal element Y, and the metal element Z contained in the metal oxide is represented by B_{X}: B_{Y}: B_{Z}, the content ratio of the metal element X can be represented by Bx/(B_{X}+B_{Y}+B_{Z}).

For example, in the case of the metal oxide containing In, higher content of In enables the transistor to have high on-state current.

With use of a metal oxide that does not contain Ga or has low Ga content in the semiconductor layer 321, the transistor can be highly reliable against positive bias application. That is, the amount of change in the threshold voltage of the transistor in the PBTS (positive bias temperature stress) test can be small. Meanwhile, with use of a metal oxide that contains Ga, the Ga content is preferably lower than the In content. In this manner, the transistor with high mobility and high reliability can be achieved.

Meanwhile, the high content of Ga enables the transistor to be highly reliable against light. That is, the amount of change in the threshold voltage of the transistor in the NBTIS (negative bias temperature illumination stress) test can be small. Specifically, in a metal oxide in which the atomic ratio of Ga is higher than or equal to the atomic ratio of In, the band gap is increased, and the amount of change in the threshold voltage of the transistor in the NBTIS test can be reduced accordingly.

Furthermore, a metal oxide having a high zinc content comes to have high crystallinity, whereby diffusion of impurities in the metal oxide can be inhibited. Consequently, a change in electrical characteristics of the transistor can be inhibited, and the reliability of the transistor can be increased.

The semiconductor layer 321 may have a stacked-layer structure of two or more metal oxide layers. The two or more metal oxide layers included in the semiconductor layer 321 may have the same composition or substantially the same composition. Employing a stacked-layer structure of metal oxide layers having the same composition can reduce the manufacturing cost because the metal oxide layers can be formed using the same sputtering target, for example. Note that a stacked-layer structure including two or more oxide semiconductor layers having different compositions may be employed.

It is preferable to use a metal oxide layer having crystallinity as the semiconductor layer 321. For example, a metal oxide layer having a CAAC (c-axis aligned crystal) structure, a polycrystalline structure, a nano-crystal (nc) structure, or the like can be used. With use of the metal oxide layer having crystallinity as the semiconductor layer 321, the density of defect states in the semiconductor layer 321 can be reduced, which enables the semiconductor device to have high reliability. Note that the CAAC structure is a crystal structure in which a plurality of nanocrystals (typically, a plurality of IGZO nanocrystals) have c-axis alignment and the plurality of nanocrystals are connected on the a-b plane without alignment. The CAAC structure has a smaller amount of crystal grain boundaries, grains, or the like on the a-b plane than a polycrystalline structure, and thus can achieve a highly reliable semiconductor device.

The higher the crystallinity of the metal oxide layer used as the semiconductor layer 321 is, the lower the density of defect states in the semiconductor layer 321 can be. By contrast, the use of a metal oxide layer having low crystallinity can achieve a transistor through which a large amount of current can flow.

A transistor using an oxide semiconductor (hereinafter referred to as an OS transistor) has much higher field-effect mobility than a transistor using amorphous silicon. In addition, the OS transistor has extremely low leakage current between a source and a drain in an off state (also referred to as off-state current), and charge accumulated in a capacitor that is connected in series with the transistor can be retained for a long period. Furthermore, the power consumption of the semiconductor device can be reduced with the OS transistor.

Since the OS transistor has a higher withstand voltage between a source and a drain than a transistor using silicon (hereinafter, referred to as a Si transistor), a high voltage can be applied between the source and the drain of the OS transistor. Furthermore, when a transistor operates in a saturation region, a change in source-drain current relative to a change in gate-source voltage can be smaller in an OS transistor than in a Si transistor.

A change in electrical characteristics of an OS transistor due to radiation irradiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

Note that a semiconductor material that can be used for the semiconductor layer 321 is not limited to the oxide semiconductor. For example, a single-element semiconductor or a compound semiconductor can be used. Examples of the single-element semiconductor include silicon (such as single crystal silicon, polycrystalline silicon, microcrystalline silicon, and amorphous silicon) and germanium. Examples of the compound semiconductor include gallium arsenide and silicon germanium. Examples of the compound semiconductor include an organic semiconductor, a nitride semiconductor, and an oxide semiconductor. These semiconductor materials may include an impurity as a dopant.

Alternatively, the semiconductor layer 321 may contain a layered substance that functions as a semiconductor. The layered substance is a general term of a group of materials having a layered crystal structure. In the layered crystal structure, layers formed by covalent bonding or ionic bonding are stacked with bonding such as the van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, a transistor having high on-state current can be provided.

Examples of the above-described layered substances include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

There is no particular limitation on the crystallinity of a semiconductor material used for the semiconductor layer 321, and any of an amorphous semiconductor, a single crystal semiconductor, and a semiconductor having crystallinity other than single crystal (a polycrystalline semiconductor, a microcrystalline semiconductor, or a semiconductor partly including crystal regions) may be used. It is preferable to use a semiconductor having crystallinity because it can inhibit degradation of the transistor characteristics.

Each of the top surfaces of the conductive layer 324 and the conductive layer 331 is in contact with the semiconductor layer 321. Here, in the case where the semiconductor layer 321 is formed using an oxide semiconductor, the use of a metal that is likely to be oxidized such as aluminum to form the conductive layer 324 or the conductive layer 331 might lead to forming an insulating oxide (e.g., aluminum oxide) between the semiconductor layer 321 and the conductive layer 324 or the conductive layer 331, and electrical continuity therebetween might be prevented. Therefore, a conductive material that is less likely to be oxidized, a conductive material that maintains low electric resistance even after being oxidized, or an oxide conductive material is preferably used for the conductive layer 324 and the conductive layer 331.

A light-transmitting oxide conductive material can be used for the conductive layer 324 and the conductive layer 331. For example, a conductive oxide such as indium oxide, zinc oxide, In—Sn oxide, In—Zn oxide, In—W oxide, In—W—Zn oxide, In—Ti oxide, In—Ti—Sn oxide, In—Sn oxide containing silicon, or zinc oxide to which gallium is added can be used. A conductive oxide containing indium has high conductivity, and thus is particularly preferable.

Since the conductive layer 324 does not necessarily have a light-transmitting property, a conductive material that absorbs or reflects part of visible light may be used for the conductive layer 324. For example, tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like can be used. Alternatively, titanium, ruthenium, tungsten, or the like can be used. These materials are preferable because they are conductive materials that are less likely to be oxidized or materials that maintain the conductivity even when oxidized.

The insulating layer 322 functions as a gate insulating layer. In the case where the semiconductor layer 321 is formed using an oxide semiconductor, an oxide insulating film is preferably used at least for a film of the insulating layer 322 which is in contact with the semiconductor layer 321. For example, one or more of silicon oxide, silicon oxynitride, aluminum oxide, aluminum oxynitride, hafnium oxide, hafnium oxynitride, gallium oxide, gallium oxynitride, yttrium oxide, yttrium oxynitride, and Ga-Zn oxide can be used. In addition, as the insulating layer 322, a nitride insulating film of silicon nitride, silicon nitride oxide, aluminum nitride, or aluminum nitride oxide can also be used. The insulating layer 322 may also have a stacked-layer structure, e.g., a stacked-layer structure including one or more oxide insulating films and nitride insulating films.

Note that in this specification and the like, an oxynitride refers to a material that contains more oxygen than nitrogen. A nitride oxide refers to a material that contains more nitrogen than oxygen.

The conductive layer 323 functions as a gate electrode and a variety of conductive materials can be used. The conductive layer 323 can be formed using, for example, one or more of chromium, copper, aluminum, gold, silver, zinc, molybdenum, tantalum, titanium, tungsten, manganese, nickel, iron, cobalt, molybdenum, and niobium; or an alloy including one or more of the above-described metals as its components. For the conductive layer 323, the nitride and the oxide that can be used for the conductive layer 324 and the conductive layer 331 may be used.

The insulating layer 328 includes a portion in contact with the semiconductor layer 321. In the case where the semiconductor layer 321 is formed using an oxide semiconductor, an oxide is preferably used for at least a portion of the insulating layer 328 which is in contact with the semiconductor layer 321 in order to improve the properties of the interface between the semiconductor layer 321 and the insulating layer 328. For example, silicon oxide or silicon oxynitride can be suitably used.

Moreover, a film from which oxygen is released by heating is preferably used for the insulating layer 328. Accordingly, oxygen can be supplied to the semiconductor layer 321 owing to heat applied during the manufacturing process of the transistor 300; thus, the amount of oxygen vacancy in the semiconductor layer 321 can be reduced, and reliability can be improved. Examples of a method for supplying oxygen to the insulating layer 328 include heat treatment in an oxygen atmosphere and plasma treatment in an oxygen atmosphere. Alternatively, an oxide film may be deposited by a sputtering method over the top surface of the insulating layer 328 in an oxygen atmosphere to supply oxygen. After that, the oxide film may be removed.

The insulating layer 328 is preferably formed by a deposition method such as a sputtering method or a plasma CVD method. In particular, a film with an extremely low hydrogen content can be deposited by employing a sputtering method as a deposition method in which a hydrogen gas is not used as a deposition gas. Consequently, supply of hydrogen to the semiconductor layer 321 is inhibited and the electrical characteristics of the transistor 300 can be stabilized.

As the insulating layer 329a and the insulating layer 329b, films which do not easily allow diffusion of oxygen are preferably used, whereby it is possible to prevent oxygen contained in the insulating layer 328 from being transmitted due to heating toward the substrate 311 side and the insulating layer 322 side through the insulating layer 329a and the insulating layer 329b, respectively. In other words, when the upper and lower sides of the insulating layer 328 are sandwiched between the insulating layer 329a and the insulating layer 329b, which do not easily allow diffusion of oxygen, oxygen contained in the insulating layer 328 can be enclosed. Accordingly, oxygen can be effectively supplied to the semiconductor layer 321.

As the insulating layer 329a and the insulating layer 329b, for example, one or more of silicon nitride, silicon nitride oxide, silicon oxynitride, aluminum oxide, aluminum oxynitride, aluminum nitride, hafnium oxide, and hafnium aluminate can be used. In particular, silicon nitride and silicon nitride oxide can be suitably used for the insulating layer 329a and the insulating layer 329b because the silicon nitride and the silicon nitride oxide themselves release fewer impurities (e.g., water and hydrogen) and are less likely to transmit oxygen and hydrogen.

In this specification and the like, the channel length L of the transistor 300 refers to the shortest distance between a portion of the semiconductor layer 321 in contact with the conductive layer 324 and a portion of the semiconductor layer 321 in contact with the conductive layer 331 as illustrated in FIG. 10B. The closer the side surfaces of the insulating layer 329a, the insulating layer 328, and the insulating layer 329b in the opening portion 320 are to being perpendicular to the substrate surface, the shorter the channel length L becomes.

The channel width W of the transistor 300 is equal to the length of the circumference of the opening portion 320. When the top surface shape of the opening portion 320 is a circular shape as illustrated in FIG. 10A and the diameter is R, the channel width W of the transistor 300 is equal to the circumference of the opening portion 320, i.e., the channel width W is π×R. When the top surface shape of the opening portion 320 is a circular shape, the channel width W of the transistor can be the smallest.

Note that in practice, the diameter of the opening portion 320 changes with depth in many cases. In this case, the average value of the diameters at three points corresponding to the highest, lowest, halfway points at the insulating layer 328 in a cross-sectional view can be used as the diameter of the opening portion 320. Note that without being limited to this, any of the diameter at the highest point, the diameter at the lowest point, and the diameter at the halfway point at the insulating layer 328 may be the diameter of the opening portion 320.

Note that although a circular shape is employed as the opening portion 320 in the above, a variety of shapes can be employed without being limited thereto. Besides the circular shape, for example, an elliptical shape or a quadrangular shape with rounded corners can be employed. Alternatively, a regular polygonal shape such as a regular triangular shape, a square shape, or a regular pentagonal shape or a polygonal shape other than the regular polygonal shape may be employed. Alternatively, when the opening portion 320 has a concave polygonal shape, which is a polygonal shape with at least one interior angle greater than 180°, such as a star polygonal shape, the channel width can be increased.

FIG. 2 is an example of the case where in the opening portion 320, the side surfaces of the insulating layer 328, the insulating layer 329a, and the insulating layer 329b are inclined upward, i.e., the side surfaces are so-called tapered shapes. Here, when an angle formed between the side surface of the insulating layer 328 in the opening portion 320 and the top surface of the insulating layer 324 positioned at the bottom portion of the opening portion 320 is denoted by an angle θ, it is preferable that the angle θ include a portion greater than or equal to 90° and less than or equal to 135°, preferably less than or equal to 125°, further preferably less than or equal to 120°, still further preferably less than or equal to 110°. As the angle θ is closer to a right angle, i.e., the side surface of the insulating layer 328 is closer to being perpendicular, the area occupied by the transistor 300 can be reduced. Note that in the case where a stack of the semiconductor layer 321, the insulating layer 322, and the conductive layer 323 can cover the side surface of the insulating layer 328, the angle θ may be less than 90°.

The semiconductor layer 321 is deposited along the side surfaces of the insulating layer 329a, the insulating layer 328, and the insulating layer 329b in the opening. At this time, as for a film deposited by a deposition method such as a sputtering method or a plasma CVD method, the thickness of a film deposited on a surface inclined to or perpendicular to the substrate surface tends to be smaller than the thickness of a film deposited on a surface horizontal to the substrate surface. Thus, when the semiconductor layer 321 is deposited by a sputtering method, the thickness of a portion in contact with the insulating layer 328 may be smaller than the thickness of a portion in contact with the top surface of the conductive layer 324 and the thickness of a portion in contact with the top surface of the conductive layer 331.

In a similar manner, the thicknesses of a portion of the insulating layer 322 and a portion of the conductive layer 323 that are formed along the side surface of the insulating layer 328 and the like in the opening can be smaller than those of a portion of the insulating layer 322 and a portion of the conductive layer 323 that are formed over the top surfaces of the conductive layer 324 and the conductive layer 331.

Meanwhile, by an ALD method or the like, a film with a uniform thickness can be deposited regardless of the tilt angle of a formation surface, so that the difference in thickness hardly occurs in the semiconductor layer 321, the insulating layer 322, the conductive layer 323, and the like in some cases.

For the substrate 311, glass, quartz, ceramic, sapphire, a resin, a metal, an alloy, a semiconductor, or the like can be used. When a flexible material is used for the substrate 311, the flexible FPC board 60 and a transistor provided in the FPC board 60 can also have flexibility, so that the flexibility of the battery module 10 can be increased and a flexible battery can be achieved.

For the substrate 311, it is possible to use polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, and the like.

Note that the above transistor may be directly formed over the substrate 311 having flexibility; alternatively, the transistor may be formed over a different substrate from the substrate 311 and then transferred to the substrate 311.

The positive electrode 20, the negative electrode 30, the separator 40, the exterior body 50, and the electrolyte 45 described with reference to FIG. 3 and the like are described below in detail.

### [Negative Electrode]

The negative electrode includes a negative electrode active material layer and a negative electrode current collector. The negative electrode active material layer includes a negative electrode active material and may further include a conductive material and a binder.

Metal foil can be used as the current collector, for example. The negative electrode can be formed by applying slurry onto the metal foil and drying the slurry. Note that pressing may be performed after drying. The negative electrode is a component obtained by forming an active material layer over the current collector.

In this specification, slurry refers to a material solution that is used to form the active material layer over the current collector and includes an active material, a binder, a solvent, and preferably also includes a conductive material mixed therewith. Slurry may also be referred to as slurry for an electrode or active material slurry; in some cases, slurry for forming a negative electrode active material layer is referred to as slurry for a negative electrode. [Negative Electrode Active Material]

As the negative electrode active material, for example, a carbon material, an oxide material, a nitride material, or an alloy-based material can be used.

As the carbon material, for example, graphite (natural graphite and artificial graphite), graphitizing carbon (soft carbon), non-graphitizing carbon (hard carbon), carbon fiber (carbon nanotube), graphene, carbon black, or the like can be used.

Examples of graphite include artificial graphite and natural graphite. Examples of artificial graphite include mesocarbon microbeads (MCMB), coke-based artificial graphite, and pitch-based artificial graphite. As artificial graphite, spherical graphite having a spherical shape can be used. For example, MCMB is preferable because it has a spherical shape in some cases. Moreover, MCMB may be preferable because it can have a small surface area with relative ease. Examples of natural graphite include flake graphite and spherical natural graphite.

Graphite has a low potential substantially equal to that of lithium metal (higher than or equal to 0.05 V and lower than or equal to 0.3 V vs. Li/Li⁺) when lithium ions are inserted into graphite (while a lithium-graphite intercalation compound is formed). For this reason, a lithium-ion battery using graphite can have a high operating voltage. In addition, graphite is preferable because of its advantages such as a relatively high capacity per unit volume, relatively small volume expansion, low cost, and a higher level of safety than that of lithium metal.

Non-graphitizing carbon can be obtained by baking a synthetic resin such as a phenol resin or an organic substance of plant origin, for example. In non-graphitizing carbon contained in a negative electrode active material of a lithium-ion battery of one embodiment of the present invention, the interplanar spacing of a (002) plane, which is measured by X-ray diffraction (XRD), is preferably greater than or equal to 0.34 nm and less than or equal to 0.50 nm, further preferably greater than or equal to 0.35 nm and less than or equal to 0.42 nm.

As the negative electrode active material, an element that enables charge and discharge reactions by an alloying reaction and a dealloying reaction with lithium can be used. For example, a material containing at least one of silicon, tin, gallium, aluminum, germanium, lead, antimony, bismuth, silver, zinc, cadmium, indium, and the like can be used. Such elements have a higher capacity than carbon; in particular, silicon has a high theoretical capacity of 4200 mAh/g. For this reason, silicon is preferably used as the negative electrode active material. Alternatively, a compound including any of the above elements may be used. Examples of the compound include SiO, Mg₂Si, Mg₂Ge, SnO, SnO₂, Mg₂Sn, SnS₂, V₂Sn₃, FeSn₂, CoSn₂, Ni₃Sn₂, Cu₆Sns, Ag₃Sn, Ag₃Sb, Ni₂MnSb, CeSb₃, LaSn₃, La₃Co₂Sn₇, CoSb₃, InSb, and SbSn. Here, an element that enables charge and discharge reactions by alloying and dealloying reactions with lithium and a compound containing the element, for example, are referred to as alloy-based materials in some cases.

In this specification and the like, “SiO” refers, for example, to silicon monoxide. SiO can alternatively be expressed as SiOx. Here, it is preferable that x be 1 or have an approximate value of 1. For example, x is preferably greater than or equal to 0.2 and less than or equal to 1.5, further preferably greater than or equal to 0.3 and less than or equal to 1.2.

As the negative electrode active material, an oxide such as titanium dioxide (TiO₂), lithium titanium oxide (Li₄Ti₅O₁₂), a lithium-graphite intercalation compound (LiₓC₆), niobium pentoxide (Nb₂O₅), tungsten oxide (WO₂), or molybdenum oxide (MoO₂) can be used.

Alternatively, as the negative electrode active material, Li₃₋ₓMₓN (M=Co, Ni, or Cu) with a Li₃N structure, which is a composite nitride of lithium and a transition metal, can be used. For example, Li_{2.6}Co_{0.4}N₃ is preferable because of its high discharge capacity (900 mAh/g and 1890 mAh/cm³).

A composite nitride of lithium and a transition metal is preferably used, in which case lithium ions are contained in the negative electrode active material and thus the negative electrode active material can be used in combination with a material for a positive electrode active material that does not contain lithium ions, such as V₂O₅ or Cr₃O₈. Note that in the case of using a material containing lithium ions as a positive electrode active material, the composite nitride of lithium and a transition metal can be used as the negative electrode active material by extracting the lithium ions contained in the positive electrode active material in advance.

A material that causes a conversion reaction can also be used as the negative electrode active material. For example, a transition metal oxide that does not form an alloy with lithium, such as cobalt oxide (CoO), nickel oxide (NiO), or iron oxide (FeO), may be used as the negative electrode active material. Other examples of the material that causes a conversion reaction include oxides such as Fe₂O₃, CuO, Cu₂O, RuO₂, and Cr₂O₃, sulfides such as CoS_{0.89}, NiS, and CuS, nitrides such as Zn₃N₂, Cu₃N, and Ge₃N₄, phosphides such as NiP₂, FeP₂, and CoP₃, and fluorides such as FeF₃ and BiF₃.

Note that one kind of negative electrode active material among the negative electrode active materials shown above can be used; alternatively, a plurality of kinds can be used in combination. For example, a combination of a carbon material and silicon or a combination of a carbon material and silicon monoxide can be used.

As another mode of the negative electrode, a negative electrode that does not contain a negative electrode active material at the completion of the fabrication of the battery may be used. As the negative electrode that does not contain a negative electrode active material, for example, a negative electrode can be used in which only a negative electrode current collector is included at the completion of the fabrication of the battery and in which lithium ions extracted from the positive electrode active material due to charging of the battery are deposited as lithium metal over the negative electrode current collector and form the negative electrode active material layer. A battery including such a negative electrode is referred to as a negative electrode-free (anode-free) battery, a negative electrodeless (anodeless) battery, or the like in some cases.

In the case where the negative electrode that does not contain a negative electrode active material is used, a film for enabling uniform lithium deposition may be provided over the negative electrode current collector. For the film for enabling uniform lithium deposition, for example, a solid electrolyte having lithium-ion conductivity can be used. As the solid electrolyte, a sulfide-based solid electrolyte, an oxide-based solid electrolyte, a polymer-based solid electrolyte, or the like can be used. In particular, the polymer-based solid electrolyte can be uniformly formed as a film over the negative electrode current collector with relative ease, and thus is suitable for the film for enabling uniform lithium deposition. As another film for enabling uniform lithium deposition, for example, a metal film that forms an alloy with lithium can be used. As the metal film that forms an alloy with lithium, for example, a magnesium metal film can be used. It is suitable for the film for enabling uniform lithium deposition because lithium and magnesium form a solid solution in a wide range of compositions.

In the case where the negative electrode that does not contain a negative electrode active material is used, a negative electrode current collector having projections and depressions can be used. In the case where the negative electrode current collector having projections and depressions is used, a depression of the negative electrode current collector serves as a cavity in which lithium contained in the negative electrode current collector is easily deposited, so that the lithium can be inhibited from being deposited in a dendrite-like shape.

### [Binder]

As the binder, a rubber material such as styrene-butadiene rubber (SBR), styrene-isoprene-styrene rubber, acrylonitrile-butadiene rubber, butadiene rubber, or ethylene-propylene-diene copolymer is preferably used, for example. Fluororubber can also be used as the binder.

As the binder, water-soluble polymers are preferably used, for example. As the water-soluble polymers, a polysaccharide or the like can be used, for example. As the polysaccharide, starch, a cellulose derivative such as carboxymethyl cellulose (CMC), methyl cellulose, ethyl cellulose, hydroxypropyl cellulose, diacetyl cellulose, or regenerated cellulose, or the like can be used. It is further preferable that such water-soluble polymers be used in combination with any of the above rubber materials.

Alternatively, as the binder, a material such as polystyrene, poly(methyl acrylate), poly(methyl methacrylate) (PMMA), sodium polyacrylate, polyvinyl alcohol (PVA), polyethylene oxide (PEO), polypropylene oxide, polyimide, polyvinyl chloride, polytetrafluoroethylene, polyethylene, polypropylene, polyisobutylene, polyethylene terephthalate, nylon, poly(vinylidene fluoride) (PVDF), polyacrylonitrile (PAN), ethylene-propylene-diene polymer, polyvinyl acetate, or nitrocellulose is preferably used.

As the binder, two or more of the above materials may be used in combination.

For example, a material having an especially significant viscosity modifying effect and another material may be used in combination. For example, a rubber material or the like has high adhesion and high elasticity but may have difficulty in viscosity modification when mixed in a solvent. In such a case, a rubber material or the like is preferably mixed with a material having an especially significant viscosity modifying effect, for example. As a material having an especially significant viscosity modifying effect, for instance, a water-soluble polymer is preferably used. As a water-soluble polymer having an especially significant viscosity modifying effect, the above-mentioned polysaccharide, for instance, a cellulose derivative such as carboxymethyl cellulose (CMC), methyl cellulose, ethyl cellulose, hydroxypropyl cellulose, diacetyl cellulose, or regenerated cellulose, starch, or the like can be used.

Note that a cellulose derivative such as carboxymethyl cellulose obtains a higher solubility when converted into a salt such as a sodium salt or an ammonium salt of carboxymethyl cellulose, and thus easily exerts an effect as a viscosity modifier. A high solubility can also increase the dispersibility of an active material or other components in the formation of slurry for an electrode. In this specification and the like, cellulose and a cellulose derivative used as a binder of an electrode include salts thereof.

A water-soluble polymer stabilizes the viscosity by being dissolved in water and allows stable dispersion of the active material and another material combined as a binder, such as styrene-butadiene rubber, in an aqueous solution. Furthermore, a water-soluble polymer is expected to be stably adsorbed onto an active material surface because it has a functional group. Many cellulose derivatives, such as carboxymethyl cellulose, have a functional group such as a hydroxyl group or a carboxyl group. Because of functional groups, polymers are expected to interact with each other and cover a large area of an active material surface.

In the case where the binder that covers or is in contact with the active material surface forms a film, the film is expected to serve also as a passivation film to suppress the decomposition of the electrolyte solution. Here, the “passivation film” refers to a film without electrical conductivity or a film with extremely low electrical conductivity; for example, a passivation film formed on the active material surface can inhibit the decomposition of an electrolyte solution at a battery reaction potential. It is desirable that the passivation film can conduct lithium ions while inhibiting electrical conduction.

### [Conductive Material]

A conductive material is also referred to as a conductivity-imparting agent or a conductive additive, and a carbon material is used. The conductive material is attached between a plurality of active materials, whereby the plurality of active materials are electrically connected to each other, and the conductivity is increased. Note that the term “attach” refers not only to a state where an active material and a conductive material are physically in close contact with each other, but also to the following states: the case where covalent bonding occurs, the case where bonding with the Van der Waals force occurs, the case where a conductive material covers part of the surface of an active material, the case where a conductive material is embedded in surface roughness of an active material, the case where an active material and a conductive material are electrically connected to each other without being in contact with each other, and the like.

An active material layer such as a positive electrode active material layer or a negative electrode active material layer preferably contains a conductive material.

For example, one kind or two or more kinds of carbon black such as acetylene black and furnace black, graphite such as artificial graphite and natural graphite, carbon fiber such as carbon nanofiber and carbon nanotube, and a graphene compound can be used as the conductive material.

As the carbon fiber, carbon fiber such as mesophase pitch-based carbon fiber or isotropic pitch-based carbon fiber can be used, for example. As the carbon fiber, carbon nanofiber, carbon nanotube, or the like can also be used. Carbon nanotube can be fabricated by, for example, a vapor deposition method.

A graphene compound in this specification and the like refers to graphene, multilayer graphene, multi graphene, graphene oxide, multilayer graphene oxide, multi graphene oxide, reduced graphene oxide, reduced multilayer graphene oxide, reduced multi graphene oxide, graphene quantum dots, and the like. A graphene compound contains carbon, has a plate-like shape, a sheet-like shape, or the like, and has a two-dimensional structure formed of six-membered rings of carbon atoms. The two-dimensional structure formed of the six-membered rings of carbon atoms may be referred to as a carbon sheet. A graphene compound may include a functional group. The graphene compound is preferably bent. The graphene compound may be rounded like carbon nanofiber.

The active material layer may contain, as a conductive material, metal powder or metal fiber of copper, nickel, aluminum, silver, gold, or the like, a conductive ceramic material, or the like.

The content of the conductive material with respect to the total amount of the active material layer is preferably greater than or equal to 1 wt % and less than or equal to 10 wt %, further preferably greater than or equal to 1 wt % and less than or equal to 5 wt %.

Unlike a particulate conductive material such as carbon black, which makes point contact with an active material, the graphene compound is capable of making low-resistance surface contact; accordingly, the electrical conduction between the particulate active material and the graphene compound can be improved with a smaller amount of the graphene compound than that of a normal conductive material. Thus, the proportion of the active material in the active material layer can be increased. Accordingly, the discharge capacity of the battery can be increased.

A particulate carbon-containing compound such as carbon black or graphite and a fibrous carbon-containing compound such as carbon nanotube easily enter a microscopic space. A microscopic space refers to a region or the like between a plurality of active materials, for example. When a carbon-containing compound that easily enters a microscopic space and a sheet-like carbon-containing compound, such as graphene, which can impart conductivity to a plurality of particles are used in combination, the density of the electrode is increased and an excellent conductive path can be formed. The battery obtained by the manufacturing method of one embodiment of the present invention has high capacity density per volume and stability, and thus is effective as an in-vehicle battery.

### [Current Collector]

As the current collector, a highly conductive material that does not alloy with a carrier ion of lithium or the like, for example, a metal such as stainless steel, gold, platinum, zinc, iron, copper, aluminum, or titanium, or an alloy thereof can be used. The current collector can have a sheet-like shape, a net-like shape, a punching-metal shape, an expanded-metal shape, or the like as appropriate.

A resin current collector can be used as the current collector. As the resin current collector, for example, a resin current collector including a resin such as polyolefin (e.g., polypropylene or polyethylene), nylon (polyamide), polyimide, vinylon, polyester, acrylic, or polyurethane, and a particulate or fibrous conductive material (also referred to as a conductive filler) can be used.

As the conductive material contained in the resin current collector, a conductive carbon material and one or more of metal materials such as aluminum, titanium, stainless steel, gold, platinum, zinc, iron, and copper can be used. For example, one kind or two or more kinds of carbon black such as acetylene black and furnace black, graphite such as artificial graphite and natural graphite, carbon fiber such as carbon nanofiber and carbon nanotube, graphene, and a graphene compound can be used as the conductive carbon material. In the case where the resin current collector is used as a positive electrode current collector, an antioxidant such as a hindered phenol-based material is further preferably used.

As the carbon fiber, carbon fiber such as mesophase pitch-based carbon fiber or isotropic pitch-based carbon fiber can be used, for example. As the carbon fiber, carbon nanofiber, carbon nanotube, or the like can also be used. Carbon nanotube can be fabricated by, for example, a vapor deposition method.

Note that the average particle diameter of the conductive material contained in the resin current collector can be greater than or equal to 10 nm and less than or equal to 10 μm, and is preferably greater than or equal to 30 nm and less than or equal to 5 μm.

The current collector preferably has a thickness greater than or equal to 5 μm and less than or equal to 30 μm.

Note that a material that does not alloy with carrier ions of lithium or the like is preferably used for the negative electrode current collector.

### [Positive Electrode]

A positive electrode includes a positive electrode active material layer and a positive electrode current collector. The positive electrode active material layer includes a positive electrode active material and may further include at least one of a conductive material and a binder. Note that the positive electrode current collector, the conductive material, and the binder described in [Negative electrode] can be used.

Metal foil can be used as the current collector, for example. The positive electrode can be formed by applying slurry onto the metal foil and drying the slurry. Note that pressing may be performed after drying. The positive electrode is obtained by forming an active material layer over the current collector.

Slurry refers to a material solution that is used to form the active material layer over the current collector and includes an active material, a binder, and a solvent, preferably also a conductive material mixed therewith. Slurry may also be referred to as slurry for an electrode or active material slurry; in some cases, slurry for forming a positive electrode active material layer is referred to as slurry for a positive electrode.

### [Positive Electrode Active Material]

As the positive electrode active material, one or more of a composite oxide having a layered rock-salt structure, a composite oxide having an olivine structure, and a composite oxide having a spinel structure can be used.

As the composite oxide having a layered rock-salt structure, one or more of lithium cobalt oxide, lithium nickel-cobalt-manganese oxide, lithium nickel-cobalt-aluminum oxide, and lithium nickel-manganese-aluminum oxide can be used. Note that the composition formula can be represented by LiM1O₂ (M1 is one or more selected from nickel, cobalt, manganese, and aluminum), and a coefficient of the composition formula is not limited to an integer.

As the lithium cobalt oxide, for example, lithium cobalt oxide to which magnesium and fluorine are added can be used. It is preferable to use lithium cobalt oxide to which magnesium, fluorine, aluminum, and nickel are added.

As the lithium nickel-cobalt-manganese oxide, for example, lithium nickel-cobalt-manganese oxide with a ratio such as nickel: cobalt: manganese=1:1:1, 6:2:2, 8:1:1, or 9:0.5:0.5 can be used. As the above-described lithium nickel-cobalt-manganese oxide, for example, lithium nickel-cobalt-manganese oxide to which one or more of aluminum, calcium, barium, strontium, and gallium are added is preferably used.

As the composite oxide having an olivine structure, one or more of lithium iron phosphate, lithium manganese phosphate, lithium cobalt phosphate, and lithium iron manganese phosphate can be used. Note that the composition formula can be represented by LiM2PO₄ (M2 is one or more selected from iron, manganese, and cobalt), but a coefficient of the composition formula is not limited to an integer.

Furthermore, a composite oxide having a spinel structure, such as LiMn₂O₄, can be used.

### [Electrolyte]

As one mode of an electrolyte, an electrolyte solution containing a solvent and an electrolyte dissolved in the solvent can be used. The electrolyte solution includes a solvent and a lithium salt. As the solvent of the electrolyte solution, an aprotic organic solvent is preferably used; for example, one kind of ethylene carbonate (EC), propylene carbonate (PC), butylene carbonate, chloroethylene carbonate, vinylene carbonate, γ-butyrolactone, γ-valerolactone, dimethyl carbonate (DMC), diethyl carbonate (DEC), ethyl methyl carbonate (EMC), methyl formate, methyl acetate, ethyl acetate, methyl propionate, ethyl propionate, propyl propionate, methyl butyrate, 1,3-dioxane, 1,4-dioxane, dimethoxyethane (DME), dimethyl sulfoxide, diethyl ether, methyl diglyme, acetonitrile, benzonitrile, tetrahydrofuran, sulfolane, sultone, and the like can be used, or two or more kinds thereof can be used in an appropriate combination at an appropriate ratio.

When ethylene carbonate (EC) and diethyl carbonate (DEC) are contained in the electrolyte solution, the volume ratio between ethylene carbonate and diethyl carbonate can be x:100−x (where 20≤x≤40) on the assumption that the total content of ethylene carbonate and diethyl carbonate is 100 vol %. More specifically, a mixed organic solvent including EC and DEC at EC:DEC=30:70 (volume ratio) can be used.

In the case where ethylene carbonate (EC), ethyl methyl carbonate (EMC), and dimethyl carbonate (DMC) are contained in the electrolyte solution, the volume ratio between ethylene carbonate, ethyl methyl carbonate, and dimethyl carbonate can be x:y:100−x−y (where 5≤x≤35 and 0<y<65) on the assumption that the total content of ethylene carbonate, ethyl methyl carbonate, and dimethyl carbonate is 100 vol %. More specifically, a mixed organic solvent including EC, EMC, and DMC at EC:EMC:DMC=30:35:35 (volume ratio) can be used.

Furthermore, for the electrolyte solution, a mixed organic solvent containing a fluorinated cyclic carbonate (also referred to as a cyclic carbonate fluoride in some cases) or a fluorinated chain carbonate (also referred to as a chain carbonate fluoride in some cases) can be used. The above mixed organic solvent further preferably includes both a fluorinated cyclic carbonate and a fluorinated chain carbonate. A fluorinated cyclic carbonate and a fluorinated chain carbonate are preferable because both of them include a substituent with an electron-withdrawing property and have a low solvation energy of a lithium ion. Accordingly, a fluorinated cyclic carbonate and a fluorinated chain carbonate are each suitable for the electrolyte solution, and a mixed organic solvent including these carbonates is suitable.

As a fluorinated cyclic carbonate, for example, fluoroethylene carbonate (FEC or F1EC), difluoroethylene carbonate (DFEC or F2EC), trifluoroethylene carbonate (F3EC), tetrafluoroethylene carbonate (F4EC), or the like can be used. Note that DFEC has isomers such as a cis-4,5 isomer and a trans-4,5 isomer. Each of these fluorinated cyclic carbonates includes a substituent with an electron-withdrawing property and thus is presumed to have a low solvation energy of a lithium ion. The substituent with an electron-withdrawing property in FEC is an F group.

Examples of the fluorinated chain carbonate include methyl 3,3,3-trifluoropropionate. An abbreviation of methyl 3,3,3-trifluoropropionate is “MTFP”. The substituent with an electron-withdrawing property in MTFP is a CF3 group.

FEC, which is a cyclic carbonate, has a high dielectric constant and thus has an effect of promoting dissociation of a lithium salt when used in an organic solvent. Meanwhile, since FEC includes a substituent having an electron-withdrawing property, a lithium ion is desolvated with FEC more easily than with ethylene carbonate (EC). Specifically, the solvation energy of a lithium ion is lower in FEC than in EC, which does not include a substituent with an electron-withdrawing property. Thus, lithium ions are likely to be extracted from surfaces of a positive electrode active material and a negative electrode active material, which can reduce an internal resistance of a secondary battery. In addition, FEC has a deep highest occupied molecular orbital (HOMO) level and thus is not easily oxidized, meaning high oxidation resistance. Meanwhile, FEC disadvantageously has high viscosity. In view of this, a mixed organic solvent including not only FEC but also MTFP is preferably used for the electrolyte solution. MTFP, which is a chain carbonate, can have an effect of reducing the viscosity of the electrolyte solution or maintaining the viscosity at room temperature (typically, 25 °C) even at low temperatures (typically, 0 °C). Moreover, MTFP has a lower solvation energy than methyl propionate (abbreviated as “MP”), which does not include a substituent with an electron-withdrawing property, but may solvate a lithium ion when used for the electrolyte solution.

The above-described organic solvent is preferably highly purified with low contents of dust particles or molecules other than the constituent molecules of the organic solvent (hereinafter also simply referred to as “impurities”, including oxygen (O₂), water (H₂O), or moisture). It is preferable that a reaction by-product in synthesis be reduced through appropriate purification. Specifically, the impurity in the electrolyte is at less than or equal to 100 ppm, preferably less than or equal to 50 ppm, further preferably less than 10 ppm. The concentration of moisture among the impurities can be detected by Karl Fischer titration.

Furthermore, it is preferable that peaks attributed to impurities in the above-described organic solvent be hardly observed by NMR measurement or the like. The expression “hardly observed” includes the case where the ratio of the integral area of the peak attributed to impurities to the integral area of the peak attributed to the main component (such a ratio is simply referred to as an integral ratio) is less than or equal to 0.005, preferably less than or equal to 0.002. An apparatus used for the NMR measurement is not particularly limited; for example, “AVANCE III 400” manufactured by Bruker Corporation can be used. Among the five peaks of acetonitrile derived from acetonitrile-ds used in a solvent in the 1H-NMR measurement, the center peak can be 1.94 ppm.

For example, in the case of MTFP, it is known that when 1H-NMR is measured using an acetonitrile-ds solvent, four peaks appear at δ of greater than or equal to 3.29 ppm and less than or equal to 3.43 ppm. However, in the case where another peak appears in the vicinity of the above range, for example, another peak appears at δ of greater than or equal to 3.24 ppm and less than or equal to 3.29 ppm, the peak is probably derived from impurities. Accordingly, when the ratio (integral ratio) of a peak area at greater than or equal to 3.24 ppm and less than or equal to 3.29 ppm to a peak area at greater than or equal to 3.29 ppm and less than or equal to 3.43 ppm is less than or equal to 0.005, preferably less than or equal to 0.002, it can be said that peaks attributed to impurities are hardly observed.

FEC and MTFP having such physical properties are preferably mixed at a volume ratio of x:100−x (where 5≤x≤30, preferably 10≤x≤20) on the assumption that the total content of a mixed organic solvent containing FEC and MTFP is 100 vol %. In other words, FEC and MTFP are preferably mixed such that the amount of MTFP is larger than that of FEC in the mixed organic solvent.

The use of one or more ionic liquids (room temperature molten salts) with non-flammability and non-volatility as the solvent of the electrolyte solution can prevent a battery from exploding and/or igniting even when the battery internally shorts out or the internal temperature increases due to overcharge or the like. An ionic liquid includes a cation and an anion, specifically, an organic cation and an anion. Examples of the organic cation used for the electrolyte solution include aliphatic onium cations such as a quaternary ammonium cation, a tertiary sulfonium cation, and a quaternary phosphonium cation, and aromatic cations such as an imidazolium cation and a pyridinium cation. Examples of the anion used for the electrolyte solution include a monovalent amide-based anion, a monovalent methide-based anion, a fluorosulfonate anion, a perfluoroalkylsulfonate anion, a tetrafluoroborate anion, a perfluoroalkylborate anion, a hexafluorophosphate anion, and a perfluoroalkylphosphate anion. [Lithium Salt]

As a lithium salt (also referred to as an electrolyte) dissolved in the above-described solvent, one of lithium salts such as LiPF₆, LiClO₄, LiAsF₆, LiBF₄, LiAlCl₄, LiSCN, LiBr, LiI, Li₂SO₄, Li₂B₁₀Cl₁₀, Li₂B₁₂Cl₁₂, LiCF₃SO₃, LiC₄F₉SO₃, LiC(CF₃SO₂)₃, LiC(C₂F₅SO₂)₃, LiN(CF₃SO₂)₂, LiN(C₄F₉SO₂)(CF₃SO₂), and LiN(C₂F₅SO₂)₂ can be used, or two or more kinds of these can be used in an appropriate combination at an appropriate ratio. The lithium salt is preferably at greater than or equal to 0.5 mol/L and less than or equal to 3.0 mol/L with respect to the solvent. Using a fluoride such as LiPF₆ or LiBF₄ enables a lithium-ion battery to have improved safety.

As the above-described electrolyte solution, it is preferable to use a highly purified electrolyte solution with low contents of dust particles or elements other than the constituent elements of the electrolyte solution (hereinafter, also simply referred to as “impurities”). Specifically, the weight ratio of impurities to the electrolyte solution is less than or equal to 1 wt %, preferably less than or equal to 0.1 wt %, further preferably less than or equal to 0.01 wt %.

### [Additive Agent]

The electrolyte solution may contain an additive agent. An additive agent can inhibit a decomposition reaction of an electrolyte which might occur on a positive electrode surface or a negative electrode surface when a battery operates at a high voltage and/or high temperatures. As the additive agent, for example, vinylene carbonate (VC), propane sultone (PS), TerT-butylbenzene (TBB), fluoroethylene carbonate (FEC), or lithium bis(oxalate)borate (LiBOB) is preferably used. LiBOB is particularly preferable because it is likely to form a favorable coating film. VC or FEC is preferable because it forms a favorable coating film on a negative electrode at the time of aging the battery or charging the battery at the initial use, which improves the cycling performance.

As the additive agent, one kind or two or more kinds of dinitrile compounds can be used. Specific examples of a dinitrile compound include succinonitrile, glutaronitrile, adiponitrile (ADN), and ethylene glycol bis(propionitrile) ether (EGBE).

Furthermore, fluorobenzene may be added to the above organic solvent. The concentration of the additive agent in the whole electrolyte solution is, for example, higher than or equal to 0.1 wt % and lower than or equal to 5 wt %. PS or EGBE is preferable because it forms a favorable coating film on a positive electrode at the time of charging and discharging, which improves the cycling performance. FB is preferable because it improves the wettability of the organic solvent with respect to the positive electrode and the negative electrode. A dinitrile compound is preferable because its nitrile groups are oriented to the positive electrode and the negative electrode to hinder oxidative decomposition of the organic solvent, whereby resistance against a high voltage can be increased. Furthermore, in the case where the negative electrode includes a current collector containing copper, a dinitrile compound is preferable because it can inhibit dissolution of copper at the time of overdischarge. A nitrile compound is preferably added in consideration of the use of the battery at a high voltage.

### [Gel Electrolyte]

A polymer gel obtained by swelling a polymer with an electrolyte solution may be used as a gel electrolyte. When a polymer gel electrolyte is used, a semisolid electrolyte layer can be provided, so that safety against liquid leakage and the like is improved. Furthermore, the battery can be thinner and more lightweight.

As a polymer that undergoes gelation, a silicone gel, an acrylic gel, an acrylonitrile gel, a polyethylene oxide-based gel, a polypropylene oxide-based gel, a fluorine-based polymer gel, or the like can be used.

As the polymer, a polymer having a polyalkylene oxide structure, such as polyethylene oxide (PEO); PVDF; polyacrylonitrile; a copolymer containing any of them; or the like can be used, for example. For example, PVDF-HFP, which is a copolymer of PVDF and hexafluoropropylene (HFP), can be used. The formed polymer may be porous.

### [Solid Electrolyte]

Instead of the electrolyte solution, a solid electrolyte including an inorganic material such as a sulfide-based or oxide-based inorganic material, a solid electrolyte including a polymer material such as a PEO (polyethylene oxide)-based polymer material, or the like can be used. When the solid electrolyte is used, a separator and/or a spacer do/does not need to be provided. Furthermore, the battery can be entirely solidified; therefore, there is no risk of liquid leakage, and thus the safety of the battery is significantly improved.

### [Separator]

When the electrolyte includes an electrolyte solution, a separator is placed between the positive electrode and the negative electrode. As the separator, for example, a separator formed using a fiber containing cellulose such as paper; nonwoven fabric; a glass fiber; ceramics; a synthetic fiber using nylon (polyamide), vinylon (polyvinyl alcohol-based fiber), polyester, acrylic, polyolefin, or polyurethane; or the like can be used. The separator is preferably processed into a bag-like shape and placed to wrap one of the positive electrode and the negative electrode.

The separator may have a multilayer structure. For example, an organic material film of polypropylene, polyethylene, or the like can be coated with a ceramic-based material, a fluorine-based material, a polyamide-based material, a mixture thereof, or the like. As the ceramic-based material, for example, aluminum oxide particles and silicon oxide particles can be used. As the fluorine-based material, for example, PVDF, polytetrafluoroethylene, or the like can be used. As the polyamide-based material, for example, nylon and aramid (meta-based aramid and para-based aramid) can be used.

When the separator is coated with the ceramic-based material, the oxidation resistance is improved; hence, degradation of the separator during high-voltage charging can be inhibited and the reliability of the battery can be improved. When the separator is coated with the fluorine-based material, the separator is easily brought into close contact with an electrode, resulting in improved output performance. When the separator is coated with the polyamide-based material, in particular, aramid, the heat resistance is improved; thus, the safety of the battery can be improved.

For example, both surfaces of a polypropylene film may be coated with a mixed material of aluminum oxide and aramid. Alternatively, a surface of a polypropylene film that is in contact with the positive electrode may be coated with a mixed material of aluminum oxide and aramid, and a surface of the polypropylene film that is in contact with the negative electrode may be coated with the fluorine-based material.

With the use of a separator having a multilayer structure, the capacity per volume of the battery can be increased because the safety of the battery can be maintained even when the total thickness of the separator is small.

### [Exterior Body]

For an exterior body included in the battery, a resin material or a metal material such as aluminum, stainless steel, or titanium can be used, for example. A film-like exterior body can also be used. As the film, for example, it is possible to use a film having a three-layer structure in which a highly flexible metal thin film or metal foil of aluminum, stainless steel, titanium, copper, nickel, or the like is provided over a film formed of a material such as polyethylene, polypropylene, polycarbonate, ionomer, or polyamide, and an insulating synthetic resin film of a polyamide-based resin, a polyester-based resin, or the like is provided over the metal thin film as the outer surface of the exterior body. Such a film with a multilayer structure can be referred to as a laminated film. At this time, the laminated film is sometimes referred to as an aluminum laminated film, a stainless steel laminated film, a titanium laminated film, a copper laminated film, a nickel laminated film, or the like using the material name of the metal layer included in the laminated film.

The material or thickness of the metal layer included in the laminated film sometimes affects the flexibility of a battery. As an exterior body used for a battery that is required to be flexible or lightweight, for example, an aluminum laminated film including a polypropylene layer, an aluminum layer, and a nylon layer is preferably used. Here, the thickness of the aluminum layer is preferably smaller than or equal to 50 μm, further preferably smaller than or equal to 40 μm, still further preferably smaller than or equal to 30 μm, yet further preferably smaller than or equal to 20 μm. Note that in the case where the thickness of the aluminum layer is smaller than 10 μm, a gas barrier property might be lowered by pinholes of the aluminum layer; thus, the thickness of the aluminum layer is desirably larger than or equal to 10 μm.

For an exterior body used for a battery whose physical intensity or safety is required, it is preferable to use a stainless steel laminated film including a polypropylene layer, a stainless steel layer, and a nylon layer. Furthermore, a polyethylene terephthalate layer may be provided over the nylon layer. Here, the thickness of the stainless steel layer is preferably smaller than or equal to 50 μm, further preferably smaller than or equal to 40 μm, still further preferably smaller than or equal to 30 μm, yet further preferably smaller than or equal to 20 μm. Note that in the case where the thickness of the stainless steel layer is smaller than 10 μm, a gas barrier property might be lowered by pinholes of the stainless steel layer; thus, the thickness of the stainless steel layer is desirably larger than or equal to 10 μm. Note that stainless steel in this specification refers to steel (i.e., an alloy of iron and carbon) containing chromium at approximately 12 % or more, and can be roughly classified into martensitic stainless steel, ferritic stainless steel, and austenite stainless steel according to the composition. Note that stainless steel to which one or more kinds of elements selected from Ti, Nb, Mo, Cu, Ni, and Si are added is also included.

Alternatively, for example, it is preferable to use a titanium laminated film including a polypropylene layer, a titanium layer, and a nylon layer. Furthermore, a polyethylene terephthalate layer may be provided over the nylon layer. Here, the thickness of the titanium layer is preferably smaller than or equal to 50 μm, further preferably smaller than or equal to 40 μm, still further preferably smaller than or equal to 30 μm, yet further preferably smaller than or equal to 20 μm. Note that in the case where the thickness of the titanium layer is smaller than 10 μm, a gas barrier property might be lowered by pinholes of the titanium layer; thus, the thickness of the titanium layer is desirably larger than or equal to 10μm.

The structure, method, and the like described in this embodiment can be used in an appropriate combination with any of the structures, methods, and the like described in the other embodiments.

### Embodiment 2

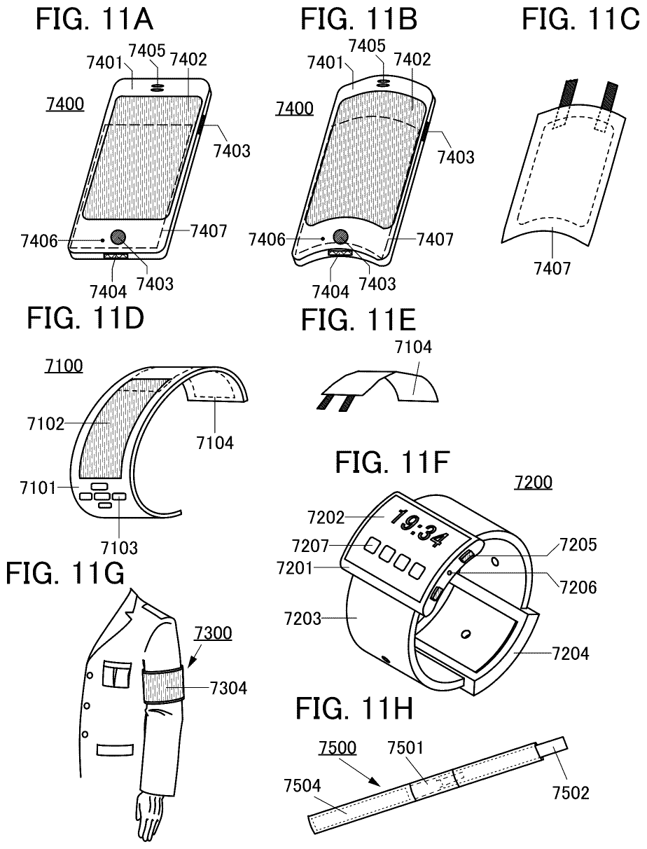

In this embodiment, examples of electronic devices including the battery of one embodiment of the present invention will be described with reference to FIG. 11A to FIG. 13C.

FIG. 11A to FIG. 11G illustrate examples of electronic devices including the battery described in the above embodiment. Examples of electronic devices including the battery include television devices (also referred to as televisions or television receivers), monitors of computers or the like, digital cameras, digital video cameras, digital photo frames, mobile phones (also referred to as cellular phones or mobile phone devices), portable game machines, portable information terminals, audio reproducing devices, and large game machines such as pachinko machines.

Furthermore, a flexible battery can be incorporated along a curved interior/exterior wall surface of a house, a building, or the like or a curved interior/exterior surface of an automobile.

FIG. 11A illustrates an example of a mobile phone. A mobile phone 7400 is provided with a display portion 7402 incorporated in a housing 7401, operation buttons 7403, an external connection port 7404, a speaker 7405, a microphone 7406, and the like. The mobile phone 7400 includes a battery 7407. When the battery of one embodiment of the present invention is used as the battery 7407, a lightweight mobile phone with a long lifetime can be provided.

FIG. 11B illustrates a state where the mobile phone 7400 is curved. When the whole mobile phone 7400 is curved by an external force, the battery 7407 included therein is also curved. FIG. 11C illustrates the battery 7407 that is being bent at that time. The battery 7407 is a thin storage battery. The battery 7407 is fixed in a state of being bent. The battery 7407 includes a lead electrode electrically connected to a current collector.

FIG. 11D illustrates an example of a bangle display device. A portable display device 7100 includes a housing 7101, a display portion 7102, operation buttons 7103, and a battery 7104. FIG. 11E illustrates the bent battery 7104. When the display device is worn on a user's arm with the battery 7104 in a state of being bent, the housing changes its shape and the curvature of part or the whole of the battery 7104 is changed. The bending condition of a curve at a given point that is represented by a value of the radius of a corresponding circle is referred to as the radius of curvature, and the reciprocal of the radius of curvature is referred to as curvature. Specifically, part or the whole of the housing or the main surface of the battery 7104 is changed within the range of 40 mm to 150 mm of radius curvature. When the radius of curvature at the main surface of the battery 7104 is within the range of 40 mm to 150 mm, the reliability can be kept high. When the battery of one embodiment of the present invention is used as the battery 7104, a lightweight portable display device with a long lifetime can be provided.

FIG. 11F illustrates an example of a watch-type portable information terminal. A portable information terminal 7200 includes a housing 7201, a display portion 7202, a band 7203, a buckle 7204, an operation button 7205, an input/output terminal 7206, and the like.

The portable information terminal 7200 is capable of executing a variety of applications such as mobile phone calls, e-mailing, viewing and editing texts, music reproduction, Internet communication, and a computer game.

The display surface of the display portion 7202 is curved, and images can be displayed on the curved display surface. In addition, the display portion 7202 includes a touch sensor, and operation can be performed by touching the screen with a finger, a stylus, or the like. For example, by touching an icon 7207 displayed on the display portion 7202, an application can be started.

With the operation button 7205, a variety of functions such as time setting, power on/off, on/off of wireless communication, setting and cancellation of a silent mode, and setting and cancellation of a power saving mode can be performed. For example, the functions of the operation button 7205 can be set freely by the operating system incorporated in the portable information terminal 7200.

The portable information terminal 7200 can employ near field communication based on an existing communication standard. For example, mutual communication with a headset capable of wireless communication enables hands-free calling.

Moreover, the portable information terminal 7200 includes the input/output terminal 7206, and data can be directly transmitted to and received from another information terminal via a connector. In addition, charging via the input/output terminal 7206 is possible. The charging operation may be performed by wireless power feeding without using the input/output terminal 7206.

The display portion 7202 of the portable information terminal 7200 includes the battery of one embodiment of the present invention. When the battery of one embodiment of the present invention is used, a lightweight portable information terminal with a long lifetime can be provided. For example, the battery 7104 illustrated in FIG. 11E can be incorporated in the housing 7201 while being curved, or can be incorporated in the band 7203 such that it can be curved.

The portable information terminal 7200 preferably includes a sensor. As the sensor, for example, a human body sensor such as a fingerprint sensor, a pulse sensor, or a temperature sensor, a touch sensor, a pressure sensitive sensor, or an acceleration sensor is preferably mounted.

FIG. 11G illustrates an example of an armband display device. A display device 7300 includes a display portion 7304 and the battery of one embodiment of the present invention. The display device 7300 can include a touch sensor in the display portion 7304 and can serve as a portable information terminal.

The display surface of the display portion 7304 is curved, and images can be displayed along the curved display surface. A display state of the display device 7300 can be changed by, for example, near field communication that is standardized communication.

The display device 7300 includes an input/output terminal, and data can be directly transmitted to and received from another information terminal via a connector. In addition, charging via the input/output terminal is possible. The charging operation may be performed by wireless power feeding without using the input/output terminal.

When the battery of one embodiment of the present invention is used as the battery included in the display device 7300, a lightweight display device with a long lifetime can be provided.

Examples of electronic devices including the battery with excellent cycling performance described in the above embodiment are described with reference to FIG. 11H to FIG. 13C.

When the battery of one embodiment of the present invention is used as a battery of a daily electronic device, a lightweight product with a long lifetime can be provided. Examples of the daily electronic device include an electric toothbrush, an electric shaver, and electric beauty equipment, and as batteries of these products, small and lightweight stick type batteries with high discharge capacity are desired in consideration of handling ease for users.

FIG. 11H is a perspective view of a device called a cigarette smoking device (electronic cigarette). In FIG. 11H, an electronic cigarette 7500 includes an atomizer 7501 including a heating element, a battery 7504 that supplies power to the atomizer, and a cartridge 7502 including a liquid supply bottle, a sensor, and the like. To improve safety, a protection circuit that prevents overcharge and/or overdischarge of the battery 7504 may be electrically connected to the battery 7504. The battery 7504 illustrated in FIG. 11H includes an external terminal for connection to a charger. When the electronic cigarette 7500 is held, the battery 7504 is a tip portion; thus, it is preferable that the battery 7504 have a short total length and be lightweight. With the battery of one embodiment of the present invention, which has high discharge capacity and excellent cycling performance, the small and lightweight electronic cigarette 7500 that can be used for a long time over a long period can be provided.

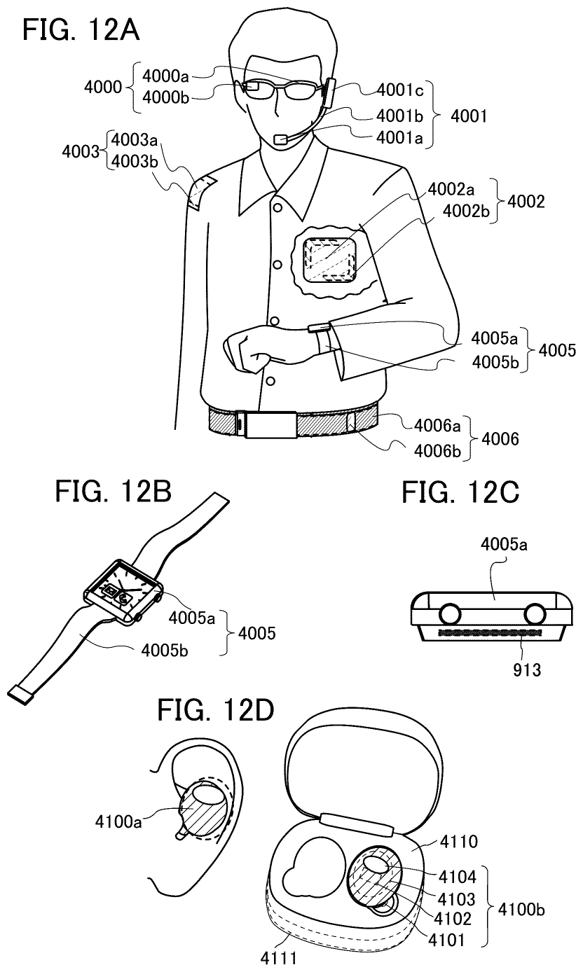

FIG. 12A illustrates examples of wearable devices. A battery is used as a power source of a wearable device. To have improved splash resistance, water resistance, or dust resistance in daily use or outdoor use by a user, a wearable device is desirably capable of being charged with and without a wire whose connector portion for connection is exposed.

For example, the battery of one embodiment of the present invention can be provided in a glasses-type device 4000 illustrated in FIG. 12A. The glasses-type device 4000 includes a frame 4000a and a display portion 4000b. The battery is provided in a temple portion of the frame 4000a having a curved shape, whereby the glasses-type device 4000 can be lightweight, can have a well-balanced weight, and can be used continuously for a long time. With the use of the battery of one embodiment of the present invention, a structure which can overcome space limitations due to miniaturization of the housing can be achieved.

The battery of one embodiment of the present invention can be provided in a headset-type device 4001. The headset-type device 4001 includes at least a microphone portion 4001a, a flexible pipe 4001b, and an earphone portion 4001c. The battery can be provided in the flexible pipe 4001b and/or the earphone portion 4001c. With the use of the battery of one embodiment of the present invention, a structure which can overcome space limitations due to miniaturization of the housing can be achieved.

The battery of one embodiment of the present invention can be provided in a device 4002 that can be attached directly to a body. A battery 4002b can be provided in a thin housing 4002a of the device 4002. With the use of the battery of one embodiment of the present invention, a structure which can overcome space limitations due to miniaturization of the housing can be achieved.

The battery of one embodiment of the present invention can be provided in a device 4003 that can be attached to clothes. A battery 4003b can be provided in a thin housing 4003a of the device 4003. With the use of the battery of one embodiment of the present invention, a structure which can overcome space limitations due to miniaturization of the housing can be achieved.

The battery of one embodiment of the present invention can be provided in a belt-type device 4006. The belt-type device 4006 includes a belt portion 4006a and a wireless power feeding and receiving portion 4006b, and the battery can be provided inside the belt portion 4006a. With the use of the battery of one embodiment of the present invention, a structure which can overcome space limitations due to miniaturization of the housing can be achieved.

The battery of one embodiment of the present invention can be provided in a watch-type device 4005. The watch-type device 4005 includes a display portion 4005a and a belt portion 4005b, and the battery can be provided in the display portion 4005a or the belt portion 4005b. With the use of the battery of one embodiment of the present invention, a structure which can overcome space limitations due to miniaturization of the housing can be achieved.

The display portion 4005a can display not only time but also a variety of information such as an e-mail and an incoming call.

The watch-type device 4005 is a wearable device that is to be wound around an arm directly; thus, a sensor that measures the pulse, the blood pressure, or the like of the user may be incorporated therein. Data on the exercise quantity and health of the user can be stored to be used for health maintenance.

FIG. 12B is a perspective view of the watch-type device 4005 that is detached from an arm.

FIG. 12C illustrates a side view. FIG. 12C illustrates a state where a battery 913 is incorporated. The battery 913 is the battery described in Embodiment 2. The battery 913 is provided in a position overlapping with the display portion 4005a and is small and lightweight.

FIG. 12D illustrates an example of wireless earphones. The wireless earphones illustrated here include, but not limited to, a pair of main bodies 4100a and 4100b.

The main bodies 4100a and 4100b each include a driver unit 4101, an antenna 4102, and a battery 4103. A display portion 4104 may also be included. Moreover, a substrate where a circuit such as a wireless IC is provided, a terminal for charging, and the like are preferably included. Furthermore, a microphone may be included.

A case 4110 includes a battery 4111. Moreover, a substrate where a circuit such as a wireless IC or a charge control IC is provided, and a terminal for charging are preferably included. Furthermore, a display portion, a button, and the like may be included.

The main bodies 4100a and 4100b can communicate wirelessly with another electronic device such as a smartphone. Thus, sound data and the like transmitted from another electronic device can be played through the main bodies 4100a and 4100b. When the main bodies 4100a and 4100b include a microphone, sound captured by the microphone is transmitted to another electronic device, and sound data obtained by processing with the electronic device can be transmitted to the main bodies 4100a and 4100b and played. Hence, the wireless earphones can be used as a translator, for example.

The battery 4103 included in the main body 4100a can be charged by the battery 4111 included in the case 4110. As each of the battery 4111 and the battery 4103, the coin-type battery of the foregoing embodiment or a cylindrical battery, for example, can be used. A battery obtained in Embodiment 1 has a high energy density; thus, with the use of the battery as the battery 4103 and the battery 4111, a structure which can overcome space limitations due to miniaturization of wireless earphones can be achieved.

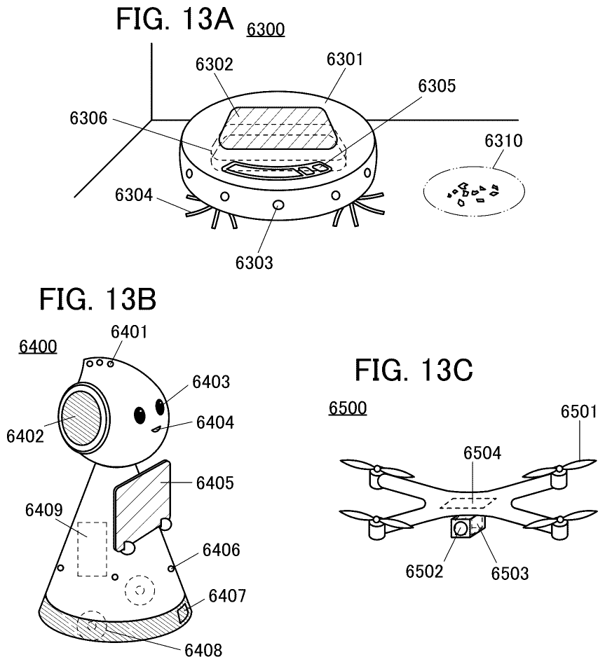

FIG. 13A illustrates an example of a cleaning robot. A cleaning robot 6300 includes a display portion 6302 placed on the top surface of a housing 6301, a plurality of cameras 6303 placed on the side surface of the housing 6301, a brush 6304, an operation button 6305, a battery 6306, a variety of sensors, and the like. Although not illustrated, the cleaning robot 6300 is provided with a tire, an inlet, and the like. The cleaning robot 6300 can be self-propelled, detect dust 6310, and suck up the dust through the inlet provided on the bottom surface.

For example, the cleaning robot 6300 can determine whether there is an obstacle such as a wall, furniture, or a step by analyzing images taken by the cameras 6303. In the case where the cleaning robot 6300 detects an object, such as a wire, that is likely to be caught by the brush 6304 by image analysis, the rotation of the brush 6304 can be stopped. The cleaning robot 6300 includes a battery 6306 of one embodiment of the present invention and a semiconductor device or an electronic component. The use of the battery 6306 of one embodiment of the present invention for the cleaning robot 6300 can make the cleaning robot 6300 a highly reliable electronic device that can operate for a long time.

FIG. 13B illustrates an example of a robot. A robot 6400 illustrated in FIG. 13B includes a battery 6409, an illuminance sensor 6401, a microphone 6402, an upper camera 6403, a speaker 6404, a display portion 6405, a lower camera 6406, an obstacle sensor 6407, a moving mechanism 6408, an arithmetic device, and the like.

The microphone 6402 has a function of detecting a speaking voice of a user, an environmental sound, and the like. The speaker 6404 has a function of outputting sound. The robot 6400 can communicate with the user using the microphone 6402 and the speaker 6404.

The display portion 6405 has a function of displaying various kinds of information. The robot 6400 can display information desired by a user on the display portion 6405. The display portion 6405 may be provided with a touch panel. Moreover, the display portion 6405 may be a detachable information terminal, in which case charging and data communication can be performed when the display portion 6405 is set at the home position of the robot 6400.

The upper camera 6403 and the lower camera 6406 each have a function of capturing an image of the surroundings of the robot 6400. The obstacle sensor 6407 can detect whether there is an obstacle in the direction where the robot 6400 advances with the moving mechanism 6408. The robot 6400 can move safely by recognizing the surroundings with the upper camera 6403, the lower camera 6406, and the obstacle sensor 6407.

The robot 6400 includes the battery 6409 of one embodiment of the present invention and a semiconductor device or an electronic component. The use of the battery of one embodiment of the present invention for the robot 6400 can make the robot 6400 a highly reliable electronic device that can operate for a long time.

FIG. 13C illustrates an example of a flying object. A flying object 6500 illustrated in FIG. 13C includes propellers 6501, a camera 6502, a battery 6503, and the like and has a function of flying autonomously.

For example, image data captured by the camera 6502 is stored in an electronic component 6504. The electronic component 6504 can analyze the image data to detect whether there is an obstacle in the way of the movement. Moreover, the electronic component 6504 can estimate the remaining battery level from a change in the power storage capacity of the battery 6503. The flying object 6500 includes the battery 6503 of one embodiment of the present invention. The use of the battery of one embodiment of the present invention for the flying object 6500 can make the flying object 6500 a highly reliable electronic device that can operate for a long time.

This embodiment can be implemented in appropriate combination with the other embodiments.

### Embodiment 3

In this embodiment, examples of vehicles including batteries of one embodiment of the present invention will be described.

The use of batteries in vehicles enables production of next-generation clean energy vehicles such as hybrid electric vehicles (HVs), electric vehicles (EVs), and plug-in hybrid electric vehicles (PHVs).

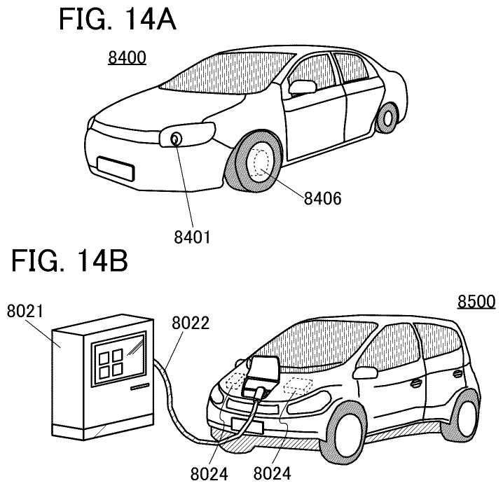

FIG. 14 illustrates examples of vehicles including the batteries of one embodiment of the present invention. An automobile 8400 illustrated in FIG. 14A is an electric vehicle that runs on the power of an electric motor. Alternatively, the automobile 8400 is a hybrid electric vehicle capable of driving using either an electric motor or an engine as appropriate. The use of one embodiment of the present invention can achieve a high-mileage vehicle. The automobile 8400 includes the battery. For example, the modules of the battery can be arranged in a floor portion in the automobile to be used. The battery can be used not only for driving an electric motor 8406, but also for supplying electric power to light-emitting devices such as a headlight 8401 and a room light (not illustrated).

The battery can also supply electric power to a display device such as a speedometer or a tachometer included in the automobile 8400. Furthermore, the battery can supply electric power to a semiconductor device such as a navigation system included in the automobile 8400.

An automobile 8500 illustrated in FIG. 14B can be charged when the battery included in the automobile 8500 is supplied with electric power through external charge equipment by a plug-in system, a contactless power feeding system, and/or the like. FIG. 14B illustrates a state where a battery 8024 included in the automobile 8500 is charged with the use of a ground-based charging apparatus 8021 through a cable 8022. In charging, a given method such as CHAdeMO (registered trademark) or Combined Charging System may be employed as a charge method, the standard of a connector, and the like as appropriate. The charging apparatus 8021 may be a charging station provided in a commerce facility or a power source in a house. For example, with the use of a plug-in technique, the battery 8024 provided in the automobile 8500 can be charged by an external electric power supply. Charging can be performed by converting AC electric power into DC electric power through a converter such as an ACDC converter.

Although not illustrated, the vehicle may include a power receiving device so that it can be charged by being supplied with electric power from an above-ground power transmitting device in a contactless manner. In the case of the contactless power feeding system, by fitting a power transmitting device in a road and/or an exterior wall, charging can be performed not only when the vehicle is stopped but also when driven. In addition, the contactless power feeding system may be utilized to perform transmission and reception of electric power between vehicles. Furthermore, a solar cell may be provided in the exterior of the vehicle to charge the battery when the vehicle stops and/or moves. To supply electric power in such a contactless manner, an electromagnetic induction method and/or a magnetic resonance method can be used.

According to one embodiment of the present invention, the battery can have improved cycling performance and an increased discharge capacity. Thus, the battery itself can be made more compact and lightweight. The compact and lightweight battery contributes to a reduction in the weight of a vehicle, and thus increases the mileage. Furthermore, the battery included in the vehicle can be used as a power supply source for supplying electric power to products other than the vehicle. In such a case, the use of a commercial power supply can be avoided at peak time of electric power demand, for example. Avoiding the use of a commercial power supply at peak time of electric power demand can contribute to energy saving and a reduction in carbon dioxide emissions.

This embodiment can be implemented in appropriate combination with the other embodiments.

### Embodiment 4

This embodiment describes examples in which the lithium-ion battery of one embodiment of the present invention is mounted on a motorcycle and a bicycle as examples of mounting a secondary battery on a vehicle.

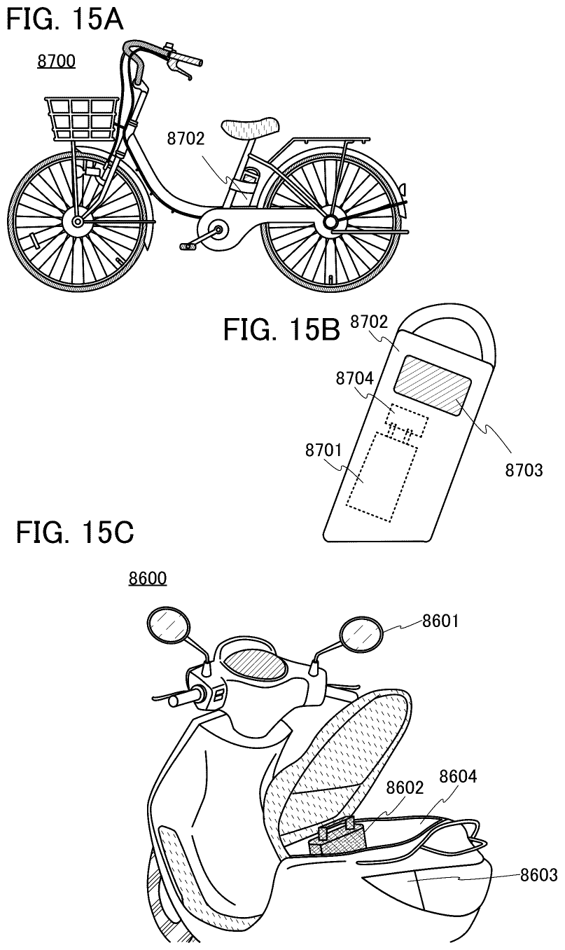

FIG. 15A illustrates an example of an electric bicycle using the power storage device of one embodiment of the present invention. The power storage device of one embodiment of the present invention can be used for an electric bicycle 8700 illustrated in FIG. 15A. The power storage device of one embodiment of the present invention includes a plurality of storage batteries and a protection circuit, for example.

The electric bicycle 8700 includes a power storage device 8702. The power storage device 8702 can supply electricity to a motor that assists a rider. The power storage device 8702 is portable, and FIG. 15B illustrates a state where the power storage device 8702 is detached from the bicycle. A plurality of storage batteries 8701 included in the power storage device of one embodiment of the present invention are incorporated in the power storage device 8702, and the remaining battery capacity and the like can be displayed on a display portion 8703.

FIG. 15C illustrates an example of a motorcycle using the power storage device of one embodiment of the present invention. A motor scooter 8600 illustrated in FIG. 15C includes a power storage device 8602, side mirrors 8601, and indicator lights 8603. The power storage device 8602 can supply electricity to the indicator lights 8603.

In the motor scooter 8600 illustrated in FIG. 15C, the power storage device 8602 can be stored in an under-seat storage unit 8604. The power storage device 8602 can be stored in the under-seat storage unit 8604 even when the under-seat storage unit 8604 is small.

This embodiment can be implemented in appropriate combination with the other embodiments.

### [Reference Numerals]

10: battery module, 11: power storage portion, 20: positive electrode, 22: positive electrode current collector, 23: positive electrode active material layer, 25: connection portion, 30: negative electrode, 32: negative electrode current collector, 33: negative electrode active material layer, 35: connection portion, 40: separator, 45: electrolyte, 50: exterior body, 51: sealing portion, 52: sealed space, 60: FPC board, 61: first resin layer, 62: first metal layer, 63: second resin layer, 64: second metal layer, 65: third resin layer, 66A: first opening portion, 66B: second opening portion, 67: bank, 70: connection terminal, 71P: plus terminal, 71N: minus terminal, 72: sealing rubber, 80: control circuit portion, 81: control IC, 82: switch, 91: transistor, 92: diode, 93: transistor, 94: resistor, 95: fuse, 96: transistor, 97: diode

1. A battery module comprising:
a flexible printed circuit board, an exterior body, a positive electrode, and a negative electrode,
wherein the flexible printed circuit board comprises a first resin layer, a second resin layer, a third resin layer, a first metal layer between the first resin layer and the second resin layer, and a second metal layer between the second resin layer and the third resin layer,
wherein the first resin layer and the exterior body are bonded to each other at a sealing portion,
wherein the positive electrode comprises a positive electrode current collector,
wherein the negative electrode comprises a negative electrode current collector, and
wherein, in a sealed space surrounded by the first resin layer, the exterior body and the sealing portion:
the first resin layer comprises a first opening portion reaching the first metal layer;
the first resin layer, the first metal layer and the second resin layer comprise a second opening portion reaching the second metal layer;
the positive electrode current collector is electrically connected to the first metal layer in the first opening portion; and
the negative electrode current collector is electrically connected to the second metal layer in the second opening portion.

2. The battery module according to claim 1,
wherein the first metal layer comprises aluminum, and
wherein the second metal layer comprises copper.

3. The battery module according to claim 1,
wherein the flexible printed circuit board comprises a control circuit portion,
wherein the control circuit portion is electrically connected to the positive electrode current collector through the first metal layer, and
wherein the control circuit portion is electrically connected to the negative electrode current collector through the second metal layer.

4. The battery module according to claim 1,
wherein the flexible printed circuit board comprises a control circuit portion and a connection terminal,
wherein the control circuit portion comprises a transistor and a control integrated circuit,
wherein the second metal layer comprises a first portion and a second portion,
wherein a gate of the transistor is connected to the control integrated circuit,
wherein one of a source and a drain of the transistor is connected to the positive electrode current collector through the first portion, and
wherein the other of the source and the drain of the transistor is connected to the connection terminal through the second portion.

5. The battery module according to claim 4, wherein the transistor is a transistor using an oxide semiconductor.

6. The battery module according to claim 4, wherein the transistor is a vertical transistor.

7. The battery module according to claim 1, wherein each of the positive electrode and the negative electrode is between the flexible printed circuit board and the exterior body.

8. The battery module according to claim 1, wherein the flexible printed circuit board, the exterior body and the sealing portion form the sealed space that seals the positive electrode and the negative electrode.

9. An electronic device comprising the battery module according to claim 1.
